(19) United States
(12) Patent Application Publication
(10) Pub. No.: US 2026/0096383 A1
(43) Pub. Date: Apr. 2, 2026

(54) FLEXIBLE CHUCK WITH STRAIN GAUGE

(71) Applicant: CANON KABUSHIKI KAISHA, Tokyo (JP)

(72) Inventors: Edward Brian Fletcher, Austin, TX (US); Seth J. Bamesberger, Austin, TX (US); Xiaoming Lu, Cedar Park, TX (US)

(21) Appl. No.: 18/902,412

(22) Filed: Sep. 30, 2024

(51) Int. Cl. H01L 21/67; G01L 5/00

(52) U.S. Cl. CPC H10P 72/0428; G01L 5/0076

(57) ABSTRACT

Some devices and systems comprise an annular flexible chuck for holding a superstrate; an air cavity enclosed in part by a flexible portion of the annular flexible chuck; a pressure controller for applying air pressure to the air cavity, while the annular flexible chuck holds the superstrate, causing the flexible portion and the superstrate to bow; strain gauges positioned on the flexible portion of the annular flexible chuck; and a controller configured to estimate a curvature of the annular flexible chuck based on strain information received from the strain gauges and adjust the shaping system based on the curvature.

### BACKGROUND

Technical Field: This application generally concerns a shaping system that includes a flexible chuck for holding a superstrate.

Background: Nano-fabrication includes the fabrication of very small structures that have features that are 100 nanometers or smaller. One application of nano-fabrication is the fabrication of integrated circuits. The semiconductor-processing industry continues to strive for larger production yields while increasing the circuits per unit area formed on a substrate. Improvements in nano-fabrication include providing greater process control and increasing throughput while also allowing continued reduction of the minimum feature dimensions of the structures formed.

Some nano-fabrication techniques are commonly referred to as nanoimprint lithography. Nanoimprint lithography is useful in a variety of applications including, for example, fabricating one or more layers of integrated devices. Examples of integrated devices include CMOS logic, microprocessors, NAND Flash memory, NOR Flash memory, DRAM memory, MRAM, 3D cross-point memory, Re-RAM, Fe-RAM, STT-RAM, MEMS, optical components, and the like.

Additionally, planarization techniques are useful in fabricating semiconductor devices. For example, the process for creating a semiconductor device may include repeatedly adding and removing material to and from a substrate. This process can produce a layered substrate with an irregular height variation (i.e., relief pattern), and, as more layers are added, the substrate's height variation can increase. The height variation negatively affects the ability to add further layers to the layered substrate. Moreover, semiconductor substrates (e.g., silicon wafers) themselves are not always perfectly flat and may include an initial surface height variation (i.e., relief pattern). One technique to address height variations is to planarize the substrate between layering procedures. A planarization technique sometimes referred to as inkjet-based adaptive planarization (IAP) involves dispensing a variable drop pattern of polymerizable material between the substrate and a superstrate, where the drop pattern varies depending on the substrate's relief pattern. A superstrate is then brought into contact with the polymerizable material, after which the material is polymerized on the substrate, and the superstrate removed.

Various lithographic patterning techniques benefit from patterning on a planar surface. In ArFi laser-based lithography, planarization improves depth of focus (DOF), critical dimension (CD), and critical dimension uniformity. In extreme ultraviolet lithography (EUV), planarization improves feature placement and DOF. In nanoimprint lithography (NIL), planarization improves feature filling and CD control after pattern transfer.

Also, some nanoimprint lithography techniques form a feature pattern in a formable material (polymerizable) layer and transfer a pattern corresponding to the feature pattern into or onto an underlying substrate. The patterning process uses a template spaced apart from the substrate, and a formable liquid is applied between the template and the substrate. The formable liquid is solidified to form a solid layer that has a pattern conforming to a shape of the surface of the template that is in contact with the formable liquid. After solidification, the template is separated from the solidified layer such that the template and the substrate are spaced apart. The substrate and the solidified layer are then subjected to additional processes, such as etching processes, to transfer a relief image into or onto the substrate that corresponds to the pattern in the solidified layer.

And a substrate with polymerized material can be further subjected to known procedures and processes for device (article) fabrication, including, for example, curing, oxidation, layer formation, deposition, doping, planarization, etching, formable material removal, dicing, bonding, packaging, and the like.

### SUMMARY

Some embodiments of a shaping system comprise an annular flexible chuck for holding a superstrate, an air cavity enclosed in part by a flexible portion of the annular flexible chuck, a pressure controller for applying air pressure to the air cavity, while the annular flexible chuck holds the superstrate, causing the flexible portion and the superstrate to bow, strain gauges positioned on the flexible portion of the annular flexible chuck, and a controller configured to estimate a curvature of the annular flexible chuck based on strain information received from the strain gauges and adjust the shaping system based on the curvature.

Some embodiments of a method comprise applying air pressure to an air cavity enclosed in part by a flexible portion of an annular flexible chuck and a superstrate of a shaping system, wherein the annular flexible chuck holds the superstrate, and wherein applying the air pressure to the air cavity causes the flexible portion and the superstrate to bow; obtaining strain information about the flexible portion of the annular flexible chuck; and adjusting the shaping system based on the strain information.

Some embodiments of a shaping system comprise an annular flexible chuck adapted to hold a superstrate; a pressure controller adapted to increase or decrease an air pressure in an air cavity enclosed in part by a flexible portion of the annular flexible chuck, wherein increasing or decreasing the air pressure while the annular flexible chuck holds the superstrate causes the flexible portion and the superstrate to bow; strain gauges that are configured to measure strain at different locations on the flexible portion of the annular flexible chuck and to generate strain measurements that indicate the measured strain; and a controller configured to estimate one or more shape-characteristic values of the annular flexible chuck based on the strain information received from the strain gauges and adjust the shaping system based on the one or more shape-characteristic values.

### BRIEF DESCRIPTION OF THE DRAWINGS

FIG. 1 illustrates an example embodiment of a shaping system.

FIG. 2A illustrates an example embodiment of a topography on a substrate.

FIG. 2B illustrates an example embodiment of a planarized surface.

FIG. 3A illustrates an example embodiment of a superstrate-chuck assembly.

FIG. 3B illustrates the example embodiment of a superstrate-chuck assembly from FIG. 3A in a view that is orthogonal to the view in FIG. 3A.

FIG. 4 illustrates the example embodiment of a superstrate-chuck assembly from FIG. 3A in a view that is orthogonal to the view in FIG. 3A.

FIGS. 5A and 5B illustrates an example embodiment of a superstrate-chuck assembly while the air cavity is pressurized.

FIG. 6 illustrates an example embodiment of an operational flow for testing the condition of a flexible member.

FIG. 7 illustrates an example embodiment of an operational flow for testing the condition of a flexible member.

FIG. 8 illustrates an example embodiment of an operational flow for recovering the shape of a flexible member.

FIG. 9 illustrates examples of the shape of the flexible portion of a flexible member.

FIG. 10 illustrates an example embodiment of an operational flow for performing a spread process.

FIG. 11 illustrates an example embodiment of an operational flow for performing a spread process.

FIG. 12 illustrates an example embodiment of an operational flow for separating a superstrate from a substrate.

FIG. 13 illustrates an example embodiment of a control device.

### DESCRIPTION

The following paragraphs describe certain explanatory embodiments. Other embodiments may include alternatives, equivalents, and modifications. Additionally, the explanatory embodiments may include several novel features, and a particular feature may not be essential to some embodiments of the devices, systems, and methods that are described herein. Furthermore, some embodiments include features from two or more of the following explanatory embodiments. Thus, features from various embodiments may be combined and substituted as appropriate.

Also, as used herein, the conjunction “or” generally refers to an inclusive “or,” although “or” may refer to an exclusive “or” if expressly indicated or if the context indicates that the “or” must be an exclusive “or.”

Moreover, as used herein, the terms “first,” “second,” “third,” and so on, do not necessarily denote any ordinal, sequential, or priority relation and may be used to more clearly distinguish one member, operation, element, group, collection, set, region, section, etc. from another without expressing any ordinal, sequential, or priority relation. Thus, a first member, operation, element, group, collection, set, region, section, etc. discussed below could be termed a second member, operation, element, group, collection, set, region, section, etc. without departing from the teachings herein.

And in the following description and in the drawings, like reference numbers designate identical or corresponding members throughout the several views.

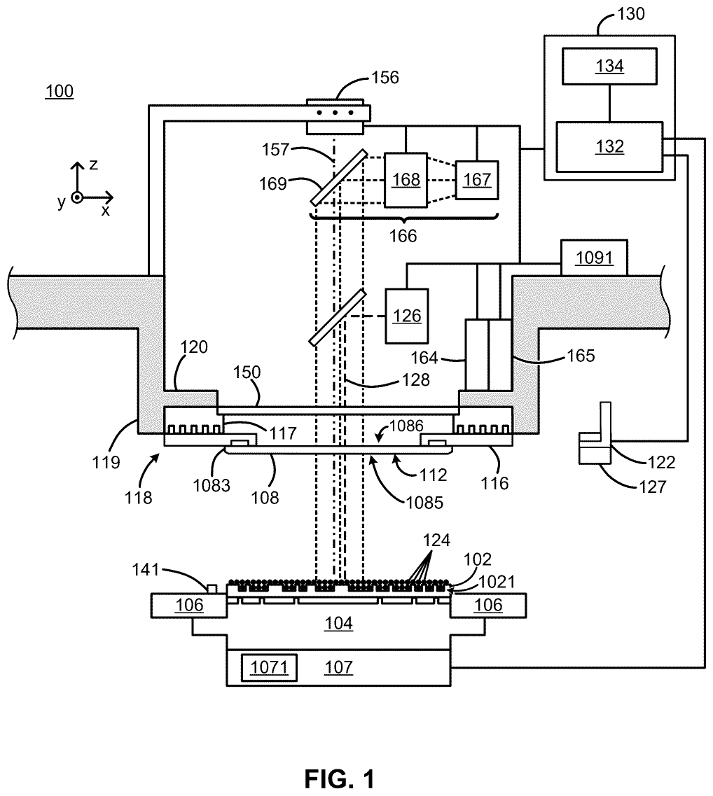

FIG. 1 illustrates an example embodiment of a shaping system 100 (e.g., a nanoimprint lithography system or an inkjet adaptive planarization system). Also, in some embodiments, the shaping system 100 is implemented as a single imprint device. When operating, the shaping system 100 deposits drops of formable material 124 (e.g., resist) on a substrate 102 and uses a plate (e.g., a superstrate 108) to, for example, planarize the formable material 124. The formable material 124 may also be referred to as planarization material.

The substrate 102 may include a topography 1021 on a surface that is proximal to the superstrate 108. In FIG. 1, the topography 1021 is a feature pattern (e.g., a relief pattern). The topography 1021 may be composed of doped regions, etched regions, or other modifications. And the topography 1021 may also be composed of cured formable material (e.g., resist, planarization material), films of insulating material, or metal. For example, the topography 1021 may be composed of etchings in one or more underlying layers. And in some embodiments, the substrate 102 is in the form of a wafer.

In the embodiment of the shaping system 100 in FIG. 1, the perimeter of the substrate 102 is surrounded by an applique 106. The applique 106 may be configured to stabilize the local gas environment beneath the superstrate 108 or to help protect the substrate 102 and the formable material 124 from particles, for example when the superstrate 108 is separated from the formable material 124 and the substrate 102. Furthermore, a back surface of the applique 106 may be below (as shown in FIG. 1) or coplanar with the substrate surface.

The substrate 102 is coupled to a substrate chuck 104, which may also support the applique 106. Examples of substrate chucks 104 include the following: vacuum chucks, pin-type chucks, groove-type chucks, electrostatic chucks, and electromagnetic chucks. In some embodiments, such as the embodiment shown in FIG. 1, the applique 106 is mounted on the substrate chuck 104 without any part of the applique being sandwiched between the substrate chuck 104 and the substrate 102. The substrate chuck 104 is supported by the substrate-positioning stage 107.

The substrate-positioning stage 107 may provide translational and/or rotational motion along one or more of the x-, y-, and z-axes, and the rotational motion may be defined by the θ, ψ, and φ angles. The substrate-positioning stage 107, the substrate 102, and the substrate chuck 104 may also be positioned on a base (not shown). Additionally, the substrate-positioning stage 107 may be a part of a positioning system or a positioning subsystem. One or more actuators 1071 (e.g., voice coil motors, piezoelectric motors, linear motors, nut and screw motors, step motors) supply the forces that move the substrate-positioning stage 107.

The shaping system 100 also includes at least one sensor 141, which is mounted on the applique 106 in this embodiment (although the sensor 141 may be mounted on the substrate chuck 104 in some embodiments). For example, the sensor 141 may be a strain sensor, a spectral-interference displacement sensor (e.g., a spectral-interference laser displacement meter, such as a micro-head spectral-interference laser displacement meter), a capacitance sensor, an air-gauge sensor, an optical-phase sensor, a polarization sensor, or the like. Also, the sensor 141 may include a light emitter that emits light, as well as a corresponding light sensor that measures an intensity of the light. In some embodiments, the sensor 141 generates signals that can be used to detect contaminants (e.g., particles) on the front surface 1085 of the superstrate 108, for example by moving the sensor 141 relative to the superstrate 108 such that the sensor 141 scans the surface of the superstrate 108. Furthermore, the sensor 141 may generate signals that can be used to measure the relative movement of a reflective (or partially reflective) face of the superstrate 108 relative to another component, such as the substrate chuck 104. Also, the sensor 141 may generate signals that can be used to detect an edge of the superstrate 108 or to detect a transition boundary on the superstrate 108. The signals from the sensor 141 may also be used by a control device 130 (described below) to estimate a center of the superstrate 108. And the sensor 141 may generate signals that indicate measurements of the shape of a flexible member 116 or the shape of the superstrate 108. For ease of illustration, the sensor 141 is illustrated as being above the applique 106. But, in some embodiments, a sensing surface of the sensor 141 is coplanar with a gas-controlling surface of the applique 106, below a gas-controlling surface of the applique 106, or below or coplanar with a chucking surface of the substrate chuck 104.

In some embodiments, the superstrate 108 is readily transparent to ultraviolet (UV) light. And examples of materials that may constitute the superstrate 108 include the following: fused-silica, quartz, silicon, organic polymers, siloxane polymers, borosilicate glass, fluorocarbon polymers, metal, and hardened sapphire.

The superstrate 108 has a front surface 1085 that faces the substrate 102, and the front surface 1085 includes a contact surface 112. The superstrate 108 also has a back surface 1086 that faces away from the substrate 102. The contact surface 112 may generally be of the same area or size as, or slightly smaller than, the front surface 1085 of the superstrate 108. The contact surface 112 of the superstrate 108 may be or may include a planar contact surface. In some embodiments (e.g., embodiments that perform Inkjet-based Adaptive Planarization (IAP)), including the embodiment in FIG. 1, the contact surface 112 of the plate (the superstrate 108 in this example embodiment) is featureless. And, in some embodiments, the contact surface 112 of the plate includes features that define a pattern that forms the basis of (e.g., an inverse of) a pattern to be formed on the substrate 102. In some embodiments, the contact surface 112 is on a mesa of the plate (the superstrate 108 in this example embodiment). In some embodiments, an area of the contact surface 112 is smaller than an area of the substrate 102, and a step-and-repeat process is used to shape a surface of formable material 124 on the substrate 102.

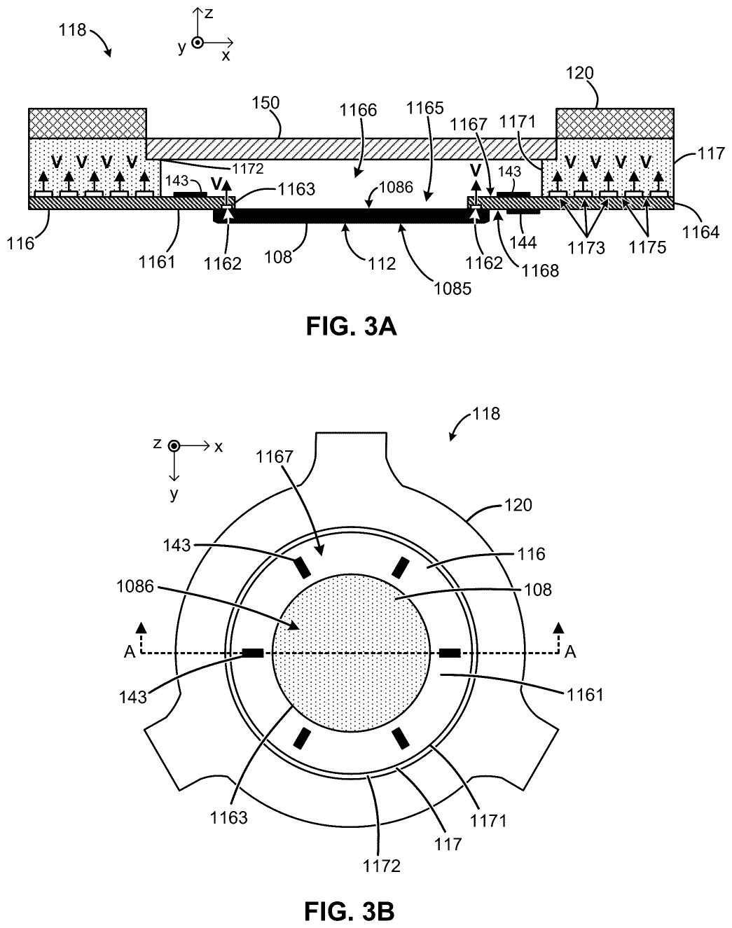

The superstrate 108 is held by a superstrate-chuck assembly 118, which is described below in more detail in the descriptions of FIGS. 3A, 3B, 4, 5A, and 5B. The superstrate-chuck assembly 118 may be coupled to an imprint head 119, which in turn may be moveably coupled to a frame 120 such that the superstrate-chuck assembly 118, the imprint head 119, and the superstrate 108 are moveable in at least the z-axis direction. For example, the imprint head 119 may include one or more actuators 1091 for controlling a relative position of the superstrate-chuck assembly 118. Non-limiting examples of such actuators include the following: voice coil motors, piezoelectric motors, linear motors, nut and screw motors, step motors, etc., that are configured to move the superstrate-chuck assembly 118 and the superstrate 108 in the z-axis direction. And in some embodiments, the superstrate-chuck assembly 118, the imprint head 119, and the superstrate 108 are also movable in one or more of the x- and y-axes directions and one or more of the θ, ψ, and φ angles. In an alternative embodiment, the head 119 is not moved in the z-axis direction, and the substrate-positioning stage 107 moves the substrate chuck 104 in the z-axis direction.

The shaping system 100 may include one or more motors or actuators that move the superstrate 108, the superstrate-chuck assembly 118, or the imprint head 119 relative to the substrate chuck 104. For example, one or more motors may rotate the superstrate 108 about an axis in the x-y plane of the superstrate 108. Rotation of superstrate 108 about an axis in the x-y plane (e.g., a rotation about the x axis, a rotation about the x axis) of the superstrate 108 changes an angle between the x-y plane of the superstrate 108 and the x-y plane of substrate 102, and may be referred herein to as “tilting” the superstrate 108 with respect to the substrate 102, changing a “tilt” or “tilt angle” of the superstrate 108 with respect to the substrate 102, or adjusting the “tilt” or “tilt angle” of the superstrate 108 relative to the substrate 102.

The shaping system 100 also includes a fluid dispenser 122. The fluid dispenser 122 may also be moveably coupled to the frame 120. In some embodiments, the fluid dispenser 122 and the superstrate-chuck assembly 118 share one or more positioning components. And in some embodiments, the fluid dispenser 122 and the superstrate-chuck assembly 118 move independently of each other. Also, in some embodiments, the fluid dispenser 122 and the superstrate-chuck assembly 118 are located in different subsystems of the shaping system 100, and the substrate 102 is moved between the different subsystems.

Different fluid dispensers 122 may use different technologies to dispense the drops of formable material 124. When the formable material is jettable, ink-jet-type fluid dispensers 122 may be used to dispense the drops of formable material 124. For example, thermal ink jetting, microelectromechanical-systems-based (MEMS-based) ink jetting, and piezoelectric ink jetting are technologies for dispensing jettable liquids.

The fluid dispenser 122 may include a fluid-dispense head 127 and fluid-dispense ports. The fluid-dispense ports may have a fixed configuration such that the fluid-dispense head 127 and fluid-dispense ports move as a unit and do not move independently of each other. Thus, the fluid-dispense ports may be fixed relative to one another on the fluid-dispense head 127. The number of fluid-dispense ports can vary between embodiments. For example, some embodiments have at least two fluid-dispense ports, at least three fluid-dispense ports, at least four fluid-dispense ports, at least five fluid-dispense ports, at least ten fluid-dispense ports, at least twenty fluid-dispense ports, or over a hundred fluid-dispense ports. In some embodiments, the fluid-dispense ports include a set of at least three fluid-dispense ports that lie along a line. In some embodiments, the fluid-dispense head 127 includes hundreds of fluid-dispense ports that lie along multiple parallel lines.

When operating, the fluid-dispense ports of the fluid dispenser 122 deposit drops of liquid formable material 124 onto the substrate 102 with the volume of deposited material 124 varying over the area of the substrate 102 based at least in part on its topography 1021. And the fluid dispenser 122 may deposit the drops of liquid formable material 124 onto the substrate 102 according to a drop pattern, which can define the distribution of the liquid formable material 124 (e.g., drop locations and drop volumes of the drops of the liquid formable material 124) on the substrate 102. The formable material 124 may be, for example, a resist (e.g., photo resist) or another polymerizable material, and the formable material 124 may comprise a mixture that includes a monomer. The drops of formable material 124 may be dispensed upon the substrate 102 before or after a desired field volume is defined between the contact surface 112 and the substrate 102, depending on the embodiment. The field volume indicates the volume of formable material 124 required to produce all of the desired features on the substrate 102 (e.g., the volume required to cover the topography 1021 with, for example, a planar surface).

Furthermore, additional formable material may be added to the substrate 102 using various techniques, for example drop dispense, spin-coating, dip coating, chemical vapor deposition (CVD), physical vapor deposition (PVD), thin film deposition, thick film deposition, or the like.

The shaping system 100 also includes an energy source 126 that directs actinic energy (e.g., ultraviolet (UV) radiation) along an exposure path 128. The imprint head 119 and the substrate-positioning stage 107 may be configured to position the superstrate 108 and the substrate 102 on (e.g., in superimposition with) the exposure path 128. The energy source 126 sends the actinic energy along the exposure path 128 after the superstrate 108 has contacted the formable material 124. For illustrative purposes, FIG. 1 shows the exposure path 128 when the superstrate 108 is not in contact with the formable material 124 so that the relative positions of the individual components can be easily identified. However, the exposure path 128 does not substantially change when the superstrate 108 is brought into contact with the formable material 124.

The shaping system 100 also includes at least one imaging device 156 (e.g., camera). FIG. 1 illustrates an optical axis 157 of the imaging device's imaging field. As illustrated in FIG. 1, the shaping system 100 may include one or more optical components (e.g., dichroic mirrors, beam combiners, prisms, lenses, mirrors) that combine the actinic energy with light to be detected by the imaging device 156. Also, the imaging device 156 may be positioned such that an imaging field of the imaging device 156 includes the superstrate 108 and such that the imaging field is in superimposition with at least part of the exposure path 128. Accordingly, the imaging device 156 may be positioned to view the spread of formable material 124 as the superstrate 108 contacts the formable material 124 during the planarization process.

Additionally, the imaging device 156 may include one or more of a CCD sensor, a CMOS sensor, a sensor array, a line camera, and a photodetector that are configured to gather light at a wavelength that shows a contrast between regions underneath the superstrate 108 and in contact with the formable material 124 and regions underneath the superstrate 108 but not in contact with the formable material 124. And the imaging device 156 may be configured to provide images of the spread of formable material 124 underneath the superstrate 108 or of the separation of the superstrate 108 from cured formable material 124. The imaging device 156 may also be configured to measure interference fringes, which change as the formable material 124 spreads between the gap between the contact surface 112 and the substrate surface and a distance between a superstrate front surface 1085 and the substrate topography varies.

In operation, once the drops of formable material 124 have been deposited on the substrate 102, either the imprint head 119, the substrate-positioning stage 107, or both vary a distance between the superstrate 108 and the substrate 102 to define a desired space (a field volume) that is filled by the formable material 124. For example, the imprint head 119 can apply a force to the superstrate 108 that moves the contact surface 112 of the superstrate 108 into contact with the drops of formable material 124 that are on the substrate 102 such that the formable material 124 spreads on the substrate 102. As the superstrate 108 contacts the drops of formable material 124, the drops merge to form a formable-material film that fills the space between the superstrate 108 and the substrate 102. Preferably, the filling process happens in a uniform manner without any air or gas bubbles being trapped between the superstrate 108 and the substrate 102 in order to minimize non-fill defects.

After the desired field volume is filled with the formable material 124, the energy source 126 produces energy (e.g., actinic radiation) that is directed along the exposure path 128 to the formable material 124 and that causes the formable material 124 to cure (e.g., solidify, cross-link) in conformance to a shape of the substrate's topography 1021 and a shape of the contact surface 112. The formable material 124 can be cured while the superstrate 108 is in contact with the formable material 124, thereby forming a planarized surface on the substrate 102 if the superstrate 108 is featureless or a patterned layer if the superstrate 108 has a pattern. Once a cured, planarized layer is formed on the substrate 102, the superstrate 108 can be separated therefrom. And the substrate 102 and the cured, planarized layer may then be subjected to additional known steps and processes for device (article) fabrication, including, for example, patterning, curing, oxidation, layer formation, deposition, doping, planarization, etching, formable material removal, dicing, bonding, and packaging, and the like. The substrate 102 may be processed to produce a plurality of articles (devices).

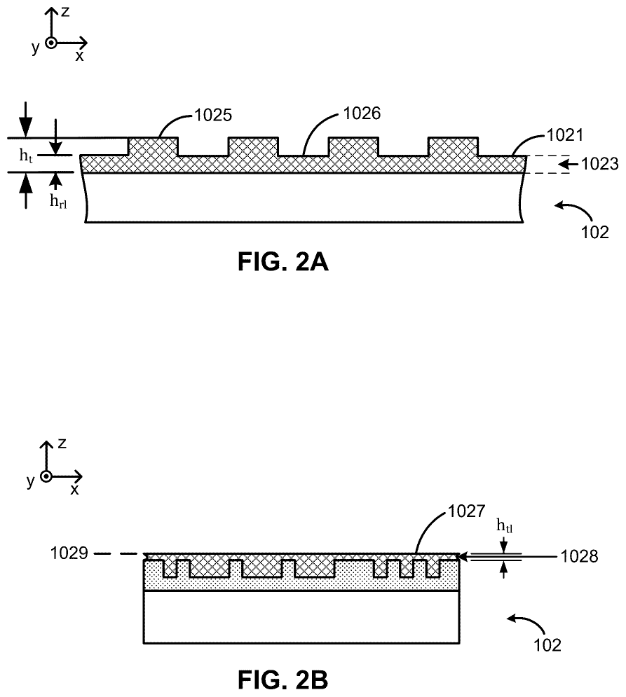

In embodiments of the shaping system 100 that perform IAP, the substrate 102 may have a topography 1021 (e.g., feature pattern) on its surface. For example, FIG. 2A illustrates an example embodiment of a topography 1021 on a substrate 102. In FIG. 2A, the substrate 102 has a topography 1021 on its back surface (which is the surface that is proximal to the superstrate 108). The topography 1021 may include a patterned film that has a residual layer 1023 and a plurality of features that are shown as protrusions 1025 and recesses 1026 that are above the residual layer 1023, which may have been made with a patterned superstrate 108. The protrusions 1025 have an imprint thickness hₜ, and the residual layer 1023 has a residual layer thickness (RLT) hᵣₗ. The topography 1021 may be a patterned substrate 102 that was, for example, etched using the patterned layer in FIG. 2A as a mask.

The drops of formable material 124 may form a patterned layer that fills the topography 1021 on the substrate 102, and the patterned layer may have a top layer that extends above the substrate 102 and that has a top layer thickness (TLT). Furthermore, the back surface of the top layer may be featureless and planar. For example, FIG. 2B illustrates an example embodiment of a planarized surface. FIG. 2B shows a cured planarized layer 1027 that has been formed on a substrate 102, which includes recesses and protrusions. The cured planarized layer 1027 fills in the recesses and protrusions in the substrate 102. The top layer 1028 of the cured planarized layer 1027, which may be referred to as the overburden, is formed above the substrate 102 and has a top layer thickness (TLT) hₜₗ. Also, a back surface 1029 of the top layer 1028 is featureless and planar.

The shaping system 100 may be regulated, controlled, or directed by one or more processors 132 in communication with one or more other components or subsystems, such as the substrate-positioning stage 107, the imprint head 119, the fluid dispenser 122, the energy source 126, the imaging device 156, or the sensor 141, and may operate based on instructions in a computer-readable program stored in one or more computer-readable storage media 134. In some embodiments, including the embodiment in FIG. 1, the one or more processors 132 and the one or more computer-readable storage media 134 are included in a control device 130. The control device 130 regulates, controls, or directs the operations of the shaping system 100. Also, the one or more processors 132 and the one or more computer-readable storage media 134 constitute a controller that regulates, controls, or directs the operations of the shaping system 100. Additionally, the control device 130 may constitute a controller, and the shaping system 100 may include a plurality of control devices 130 (at least some of which may constitute respective controllers). Some embodiments of the shaping system include one or more on-tool controllers and several local controllers that receive setpoint controls from the one or more on-tool controllers. The on-tool controllers may receive instructions from tool databases.

Each of the one or more processors 132 may be or may include one or more of the following: a central processing unit (CPU), which may include microprocessors (e.g., a single core microprocessor, a multi-core microprocessor); a graphics processing unit (GPUs); an application-specific integrated circuit (ASIC); a field-programmable-gate array (FPGA); a digital signal processor (DSP); a specially-configured computer; and other electronic circuitry (e.g., other integrated circuits). For example, a processor 132 may be a purpose-built controller or may be a general-purpose controller that has been specially-configured to be an shaping-system controller. The one or more processors 132 may include a plurality of processors that include (i) processors that are included in the control device 130 and (ii) processors that are in communication with the shaping system 100 but not included in the control device 130. And the one or more processors 130 are an example of a processing unit.

Examples of computer-readable storage media 134 include, but are not limited to, a magnetic disk (e.g., a floppy disk, a hard disk), an optical disc (e.g., a CD, a DVD, a Blu-ray), a magneto-optical disk, magnetic tape, semiconductor memory (e.g., a non-volatile memory card, flash memory, a solid-state drive, SRAM, DRAM, EPROM, EEPROM), a networked attached storage (NAS), an intranet-connected computer-readable storage device, and an internet-connected computer-readable storage device.

In the embodiment in FIG. 1, the control device 130 may operate as a drop-pattern-generation device, which generates one or more drop patterns (dispense patterns), and the control device 130 may obtain the one or more drop patterns from another device (e.g., a drop-pattern-generation device) that generated (or that store) the one or more drop patterns. For example, the one or more processors 132 may be in communication with a networked computer on which analysis is performed and control files, such as drop patterns, are generated. A drop pattern indicates where the fluid dispenser 122 should deposit drops of liquid formable material 124 onto the substrate 102. A drop pattern may be generated based, at least in part, on one or more of the following: a field volume, a feature pattern 1021 of the substrate 102, and any pattern that may be on the contact surface 112. Also, to account for the feature pattern 1021 of the substrate 102, the drop density of the drop pattern may vary across the substrate 102. And the drop pattern may have a uniform drop density over regions of the substrate 102 that have a uniform density (e.g., blank areas, or areas where the feature pattern 1021 has a uniform feature density).

The shaping system 100 may also include a substrate-heating subsystem 166 (which is an example of a substrate heating unit). The substrate-heating subsystem 166 deforms a region on the substrate 102 by heating the region on the substrate 102, and the heating may be performed before any formable material 124 has been deposited on the substrate 102, before formable material 124 that has been deposited on the substrate 102 is shaped, planarized, or imprinted, before formable material 124 that has been deposited on the substrate 102 is cured, or while formable material 124 that has been deposited on the substrate 102 is being cured.

The substrate-heating subsystem 166 includes a heating light source 167, which irradiates the substrate 102 with light to heat the substrate 102; an adjusting unit 168, which adjusts the irradiation amount (irradiation amount distribution) of the light; and a reflecting plate 169, which defines an optical path to guide light from the adjusting unit 168 to the substrate 102. In some embodiments, the substrate heating subsystem 166 is a heat source which may or may not include the heating light source 167 and is incorporated into the substrate chuck 104.

The heating light source 167 emits light that has a wavelength to which the formable material 124, as an ultraviolet curing material, is not photosensitive (not cured), for example, light in a wavelength band of 400 nm to 2,000 nm. For heating efficiency, some embodiments of the heating light source 167 emit light in a wavelength band of 500 nm to 800 nm. However, some embodiments of the heating light source 167 emit light in other wavelength bands. Also, in some embodiments, the heating light source 167 is a laser, such as a high-power laser or an LED array.

The adjusting unit 168 allows only specific light of the emitted light to irradiate the substrate 102 in order to form a predetermined irradiation-amount distribution on the substrate 102. In some embodiments, the adjusting unit 168 includes one or more spatial light modulators (SLMs). An example of an SLM is a mirror array having an array of a plurality of mirrors, each including a drive axis, which may be referred to as digital mirror device (DMD), such as a digital micro-mirror device. A DMD can control (change) an irradiation amount distribution by individually adjusting the plane direction of each mirror.

Furthermore, the imaging device 156 can detect (capture images of) alignment marks and overlay marks. Substrates 102 and superstrates 108 may include corresponding pairs of alignment marks that allow real-time alignment of the superstrates 108 and the substrates 102. After a superstrate 108 is positioned over a substrate 102 (e.g., superimposed over the substrate 102), the control device 130 determines an alignment of the superstrate-alignment marks with respect to the substrate-alignment marks based on the signals (e.g., images) from the imaging device 156. Alignment schemes may include measurement of alignment errors associated with pairs of corresponding alignment marks, followed by compensation of these errors to achieve accurate alignment of the superstrate 108 and a desired imprint location on the substrate 102.

Additionally, substrates 102 and superstrates 108 may include corresponding pairs of overlay marks that allow for assessment of and compensation for overlay errors in imprinted substrates 102. Overlay marks in a superstrate 108 are transferred to the polymeric layer (cured planarized layer 1027) during polymerization of the formable material 124, yielding a planarized (or imprinted) substrate 102 with corresponding pairs of overlay marks. The control device 130 may assess overlay errors of corresponding pairs of overlay marks in an imprinted substrate 102 to determine in-plane and out-of-plane contributions to overlay errors. In some alternative embodiments, the superstrate 108 does not have any superstrate-alignment marks, and alignment is based on a superstrate edge 1083 or a contact surface 112 of the superstrate 108. Also, some embodiments include superstrate-alignment marks and also can perform alignment based on a superstrate edge 1083 or a contact surface 112 of the superstrate 108.

And, as noted above, one or both of the substrate-positioning stage 107 and the imprint head 119 can be moved (e.g., translated, rotated) to change the relative positions of the substrate 102 and the superstrate 108. Also, the tilt of the superstrate 108 (or, in some embodiments, the tilt of the substrate 102) can be adjusted. For example, the shaping system 100 may include actuators 1091 (or other devices) that can translate the superstrate 108 about orthogonal axes (the x and y axes in FIG. 1) in the plane of the superstrate 108, rotate the superstrate 108 about an axis orthogonal to the plane of the superstrate 108 (the z axis in FIG. 1), or both. Also for example, some embodiments of the shaping system 100 may translate the superstrate 108 along the z axis and rotate the superstrate 108 about an axis in the plane of the superstrate 108 (the x and y axes in FIG. 1).

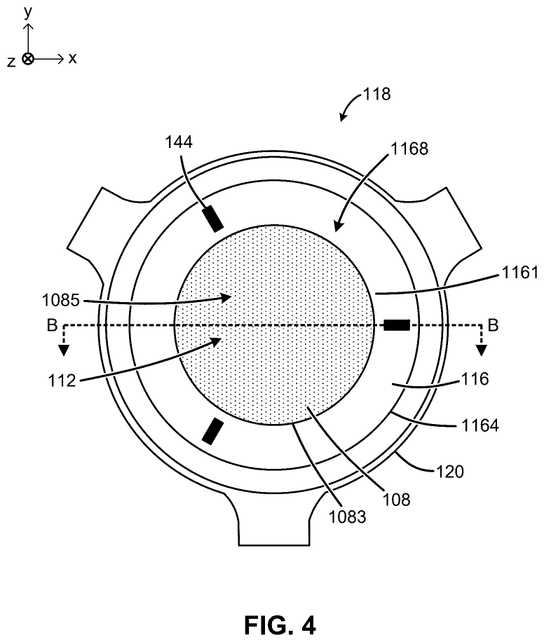

As noted above, the shaping system 100 also includes a superstrate-chuck assembly 118. FIGS. 3A, 3B, and 4 illustrate an example embodiment of a superstrate-chuck assembly 118 (chuck assembly 118). FIG. 3A is a sectional view that is taken along the plane that is indicated by the line AA in FIG. 3B and by the line BB in FIG. 4. FIG. 3B illustrates the example embodiment of the superstrate-chuck assembly 118 in a view that is orthogonal to the view in FIG. 3A, looking in the negative z-axis direction (and FIG. 3B omits the light-transmitting member 150). FIG. 4 illustrates the example embodiment of a superstrate-chuck assembly 118 in a view that is orthogonal to the view in FIG. 3A, looking in the positive z-axis direction.

The chuck assembly 118 includes a flexible member 116 (e.g., a flexible ring portion), which may have an annular shape (e.g., a circular shape) or another shape (e.g., a polygon with a hole) that is formed from the region between two concentric polygons (e.g., squares, rectangles). Thus, the flexible member 116 has both an inner perimeter 1163 and an outer perimeter 1164 and has a central opening 1165. And the shape of the outer perimeter 1164 or the inner perimeter 1163 of the flexible member 116 may be the same as, or similar to, the shape of the superstrate 108. Also, the flexible member 116 may be made of a transparent material that allows UV light to pass through or may not be made of a transparent material that allows UV light to pass through. Thus, the flexible member 116 may or may not be composed of a material that is opaque to UV light. Also, the flexible member 116 may be composed of a plastic (e.g., acrylic), a glass (e.g., fused silica, borosilicate), metal (e.g., aluminum, stainless steel), or a ceramic (e.g., zirconia, sapphire, alumina).

The flexible member 116 includes a flexible portion 1161. As discussed below in more detail, the size or shape of the flexible portion 1161 of the flexible member 116 may vary, for example while performing the planarization process or while registering the substrate 102 to the superstrate 108. Any part of the flexible member 116 that is not included in the flexible portion 1161 may be more rigid than the flexible portion 1161 (e.g., may not be flexible). For example, the portions of the flexible member 116 that are closer to the outer perimeter 1164 than to the inner perimeter 1163 may be more rigid than the flexible portion 1161. Accordingly, for example, in some embodiments in which the flexible member 116 has a circular outer perimeter 1164, the flexible portion 1161 has an annular shape, and the other portions of the flexible member 116 (the portions that are not included in the flexible portion) have an annular shape that surrounds the flexible portion 1161.

In some embodiments, for example, the thickness of the flexible member 116, including the flexible portion 1161, may be from 0.2 to 5 mm or 0.3 to 2 mm. Also for example, the length of the flexible portion 1161 at a point in the process when the flexible portion 1161 is shortest may be 10 mm to 200 mm or 20 to 75 mm in some embodiments. And, for example, the ratio of the length of the flexible portion 1161 to the thickness of the flexible portion 1161 may be 1000:1 to 2:1 in some embodiments. In some example embodiments, the ratio of the length of the flexible portion 1161 to the thickness of the flexible portion 1161 may be 5:1 to 200:1. A thicker material with a low elastic modulus will have a flexibility that is similar to the flexibility of a thin material with high elastic modulus. The flexible member 116 may be composed of a material having a modulus of elasticity (Young's modulus) of 1 to 210 GPa, 50 to 150 GPa, or 60 to 100 GPa. In some embodiments, the modulus of elasticity may be 70 GPa.

Some example embodiments of the flexible member 116 have a flexural rigidity of 0.01 to 5 Pa·m³, 0.1 to 4 Pa·m³, 0.5 to 3 Pa·m³, 1.0 to 2 Pa·m³. Additionally, a ratio of the flexural rigidity of the flexible member 116 to the flexural rigidity of the superstrate 108 may be 0.01:1 to 5:1, 0.05:1 to 4:1, 0.1:1 to 3:1, or 0.5:1 to 1:1, and may preferably be less than 1:1 in some embodiments. Equation (1) below defines the flexural rigidity D:

$$D = \frac{{EH}^{3}}{12 ( 1 - {v}^{2} )} , \qquad ( 1 )$$

where H is the thickness of the superstrate 108 or the flexible portion 1161 of the flexible member 116; where v is Poisson's ratio of the material of the superstrate 108 or the flexible portion 1161 of the flexible member 116; and where E is Young's modulus of the material of the superstrate 108 or the flexible portion 1161 of the flexible member 116. For example, the flexural rigidity for the superstrate 108 may be 2.12, while the flexural rigidity of the flexible portion 1161 of the flexible member 116 may be 0.29, 0.68, 0.82, or 2.30 Pa·m³. And, for example, the ratio of the flexural rigidity of the flexible portion 1161 of the flexible member 116 to the flexural rigidity of the superstrate 108 may be 0.14:1, 0.32:1, 0.39:1, or 1.09:1.

The flexible member 116 may further include a superstrate-holding cavity 1162 configured to hold a portion of the superstrate 108 to the flexible portion 1161 of the flexible member 116. For example, in some embodiments the superstrate-holding cavity 1162 is annular cavity that concentrically surrounds the central opening 1165. The superstrate-holding cavity 1162 may be located adjacent to the edge of the inner perimeter 1163 of the member. And the superstrate-holding cavity 1162 may be formed as a recessed portion in the flexible portion 1161. In some embodiments, the inner diameter of the flexible member 116 is smaller or the superstrate-holding cavity 1162 has additional lands.

The chuck assembly 118 may further include a light-transmitting member 150 that is above the central opening 1165 of the flexible member 116. In some embodiments, the light-transmitting member 150 is transparent to UV light with high UV light transmissivity. That is, the material composition of the light-transmitting member 150 may be selected such that UV light used to cure the formable material passes through the light-transmitting member 150. In some embodiments in which the light-transmitting member 150 transmits UV light, the light-transmitting member 150 is composed of a material (e.g., sapphire, fused silica) that transmits greater than 80% of light having a wavelength of 310-700 nm (i.e., UV light and visible light). And in some embodiments, the light-transmitting member 150 is not transparent to UV light. When the light-transmitting member 150 is not transparent to UV light, the light-transmitting member 150 may be composed of a material (e.g., glass, borosilicate) that transmits greater than 80% of light having a wavelength of 400-700 nm (i.e., visible light). That is, in embodiments in which it does not transmit UV light, the light-transmitting member 150 may be able to transmit visible light. Also, the light-transmitting member 150 may transmit light that is emitted by the heating light source 167.

Furthermore, the chuck assembly 118 may include an air cavity 1166. In FIGS. 1, 3A, 5A, and 5B, the surfaces of the air cavity 1166 are formed, at least in part, by an underside surface of the light-transmitting member 150 and a back surface 1167 of the flexible member 116. The surfaces of the air cavity 1166 may be further formed by the inner side wall 1171 of a support ring 117, which is described in more detail below. When the flexible member 116 holds a superstrate 108, the back surface 1086 of the superstrate 108 also forms a surface of the air cavity 1166.

And the chuck assembly 118 may further include a fluid path in communication with the air cavity 1166 for pressurizing the air cavity 1166. As used herein, pressurizing includes both positive pressurizing and negative pressurizing. The fluid path can also be used to open the air cavity 1166 to the surrounding atmosphere. Also, the fluid path is in communication with one or more pressure sources 164 or vacuum sources 165 (e.g., pumps, tanks, fans) or includes one or more ports that can be coupled to pressure sources 164 or vacuum sources 165. And the fluid path may include components (e.g., one or more valves) that together allow the air cavity 1166 to be selectively positively or negatively pressurized. The one or more pressure sources 164 or vacuum sources 165 constitute a pressure controller, which operates based on signals sent from the one or more processors 132. The pressure controller may include one or more of the following: PID controllers, mass flow controllers, valves, switches, tanks, pumps, etc. that are used to control the dynamic state of fluid in the air cavity 1166. The pressure controller includes electronic components and mechanical components that temporally modulate a pressure of one or more fluids that are supplied to one or more cavities (e.g., the air cavity 1166) of the shaping system 100. The fluid modulated by a pressure supplier (a pressure source 164 or a vacuum source 165) may be supplied from a tank in the shaping system 100 or may be supplied via an external fluid supply.

The superstrate 108 may be held by the flexible portion 1161 by reducing the pressure in the superstrate-holding cavity 1162. One manner of reducing the pressure in the superstrate-holding cavity 1162 is to produce a vacuum in the superstrate-holding cavity 1162. In order to produce a vacuum in the superstrate-holding cavity 1162 of the flexible member 116, the chuck assembly 118 may further include a path (also referred herein as a vacuum path) in communication with the superstrate-holding cavity 1162 and in communication with a vacuum source 165. In a case that there is already a pressure differential within the assembly relative to the atmosphere around the assembly, the vacuum path can be used as a manner of reducing pressure in the superstrate-holding cavity 1162 without being coupled to a vacuum source 165. The vacuum path may include components (e.g., valves) that together allow the superstrate-holding cavity 1162 to generate a vacuum that applies a suction force V to the superstrate 108.

One or more additional vacuum paths may be implemented that have the same structure as the above-described vacuum path, where each vacuum path is in communication with the same superstrate-holding cavity 1162 or in communication with a corresponding additional superstrate-holding cavity (not shown) formed in the flexible member 116. The additional superstrate-holding cavity or superstrate-holding cavities may be disposed concentrically around the superstrate-holding cavity 1162. That is, the additional superstrate-holding cavity or superstrate-holding cavities may also be concentrically disposed around the central opening 1165, but may be located at a greater radial distance from the inner perimeter 1163 than the illustrated superstrate-holding cavity 1162. Also for example, an additional vacuum path having the same structure as the vacuum path may be located at a position diametrically opposing the vacuum path. The additional superstrate-holding cavity or superstrate-holding cavities may be used to assist in separating the superstrate 108 from a cured layer as part of the planarization process. And the additional superstrate-holding cavity or superstrate-holding cavities allow the same chuck assembly 118 to be used with different-sized superstrates.

In some embodiments, the superstrate-holding cavity 1162 and the vacuum path are replaced with another mechanism for coupling the flexible member 116 with a superstrate 108. For example, in place of a cavity-vacuum arrangement, an electrode that applies an electrostatic force may be included. Another option is mechanical latching where a mechanical structure on the underside of the flexible member 116 is mateable with the superstrate 108.

The chuck assembly 118 may further include a support ring 117, which may also be referred to as a ring chuck. The support ring 117 does not need to be made of a transparent material that allows for UV light to pass through. Thus, the support ring 117 may be composed of a material that is opaque to UV light. For example, the support ring 117 may be composed of plastic (e.g., acrylic), glass (e.g., fused silica, borosilicate), metal (e.g., aluminum, stainless steel), or ceramic (e.g., zirconia, sapphire, alumina). In some embodiments, the support ring 117 is composed of the same material as the flexible member 116.

The support ring 117 may include a circular (or polygonal shaped) main body defining an open central area, and the shape of the support ring 117 may be the same as, or similar to, the shape of the flexible member 116. The outer circumference of the support ring 117 may be uniform. The inner side wall 1171 of the support ring 117 may include a step that provides a receiving surface 1172 for receiving the light-transmitting member 150. Accordingly, the light-transmitting member 150 may be placed onto the receiving surface 1172 of the step, thereby covering the central area. The light-transmitting member 150 may be secured onto the receiving surface 1172, for example using an adhesive. Thus, when the light-transmitting member 150 is placed or secured onto the receiving surface 1172 and when a superstrate 108 is held by the flexible member 116, the air cavity 1166 is defined by the underside surface of the light-transmitting member 150, the inner side wall 1171 of the support ring 117, the back surface 1167 of the flexible member 116, and the back surface 1086 of the superstrate 108.

The flexible member 116 may be coupled to the underside surface of the support ring 117 using a coupling member (not shown), such as a screw, nut, bolt, adhesive, and the like. The coupling member may be located adjacent to the outer edge of the support ring 117 and adjacent to the outer edge of the flexible member 116. When the coupling member is a screw, the coupling member may pass through the flexible member 116 adjacent to the outer edge and into the support ring 117 adjacent to the outer edge. When the coupling member is an adhesive, the coupling member may be located between the flexible member 116 adjacent to the outer edge and the support ring 117 adjacent to the outer edge. In this manner, a back surface of the flexible member 116 contacts and is fixed to the underside surface of the support ring 117 adjacent to their outer edges.

Additional surface area of the flexible member 116 may be selectively coupled to the support ring 117. The chuck assembly 118 may include additional vacuum paths that allow the flexible member 116 to be selectively secured to the underside surface of the support ring 117. The additional vacuum paths that allow the flexible member 116 to be selectively secured to the underside surface of the support ring 117 may be annular cavities 1173 in the support ring 117 that are open on the underside surface of the support ring 117. When the additional vacuum paths are connected to a vacuum source 165 (e.g., a vacuum pump), and the upper side surface of the flexible member 116 is in contact with the underside surface of the support ring 117, vacuums can be generated in the annular cavities 1173 of the support ring 117 to apply suction forces V to secure the flexible member 116 to the support ring 117.

Because the annular cavities 1173 have different radial locations, each of the annular cavities 1173 will apply a suction force V to a different section of the upper side surface of the flexible member 116. Furthermore, in embodiments in which each of the annular cavities 1173 are in communication with a respective vacuum source 165 (e.g., vacuum pump) via a respective distinct vacuum path or the annular cavities 1173 are independently selectable (e.g., using one or more valves), vacuums can be independently generated in each of the annular cavities 1173. And if a vacuum is generated in only one of the annular cavities 1173, then the suction force V will be applied only to the section of upper side surface of the flexible member 116 that contacts that annular cavity 1173. However, if a vacuum is generated in two or more of the annular cavities 1173 at the same time, then suction forces will be applied on a larger section of the upper side surface of the flexible member 116, the larger section being formed by the sections of the upper side surface of the flexible member 116 that contact the two or more of the annular cavities 1173 where the vacuums are generated.

The number of the annular cavities 1173 may be selected to provide the optimal control over how much surface area of the flexible member 116 is suctioned underneath the support ring 117. For example, in some embodiments, the number of annular cavities 1173 ranges from 1 to 10, from 3 to 7, or from 4 to 6. And the annular cavities 1173 may have varying sizes. Also, for example, the ratio of the cross sectional area of one of the annular cavities 1173 to the cross sectional area of another one of the annular cavities 1173 may be from 10:1 to 1:1, from 8:1 to 4:1, or from 5:1 to 3:1. Some of the annular cavities 1173 may have the same size and shape. And, in some embodiments, the annular cavities 1173 have a cross-sectional shape that is rectangular, square, or semi-circular. The support ring 117 may further include lands 1175 between adjacent annular cavities. The lands 1175 are the portions of the support ring 117 that come into contact with the back surface of the flexible member 116.

The superstrate-chuck assembly 118 may also include one or more strain gauges (strain sensors) that measure the strain of the flexible portion 1161 of the flexible member 116 and output strain information, which includes strain measurements, that indicates the measured strain. The strain gauges may include back-side strain gauges 143 and front-side strain gauges 144. Back-side strain gauges 143 are positioned on the back surface 1167 of the flexible portion 1161 of the flexible member 116. Front-side strain gauges 144 are positioned on a front surface 1168 of the flexible portion 1161 of the flexible member 116. And some embodiments include back-side strain gauges 143 but no front-side strain gauges 144, and some embodiments include front-side strain gauges 144 but no back-side strain gauges 143. Although FIG. 3B shows six back-side strain gauges 143, some embodiments include more (e.g., 8, 9, 10, 12, 15, 20) or fewer (e.g., 1, 2, 3, 4) back-side strain gauges 143. And, in some embodiments, the back-side strain gauges 143 are arranged differently than is shown in FIG. 3B. Also, although FIG. 4 shows three front-side strain gauges 144, some embodiments include more (e.g., 4, 5, 6, 8, 9, 10, 12, 15, 20) or fewer (one or two) front-side strain gauges 144. And, in some embodiments, the front-side strain gauges 144 are arranged differently than is shown in FIG. 4.

Examples of the back-side strain gauges 143 and the front-side strain gauges 144 include the following: linear strain gauges, Rosette strain gauges, and double parallel strain gauges. The strain gauges may be configured in quarter bridge, half-bridge, or full bridge configurations. Also, in some embodiments, the strain of the flexible member 116 may be measured by non-contact techniques, and the strain gauges (back-side strain gauges 143, the front-side strain gauges 144) may include non-contact strain gauges, for example digital-image-correlation (DIC) strain gauges. And the back-side strain gauges 143 and the front-side strain gauges 144 may not all be the same type of strain gauge.

The control device 130 can use the strain information to measure or calculate the shape of the flexible portion 1161 when the shape of the flexible portion changes.

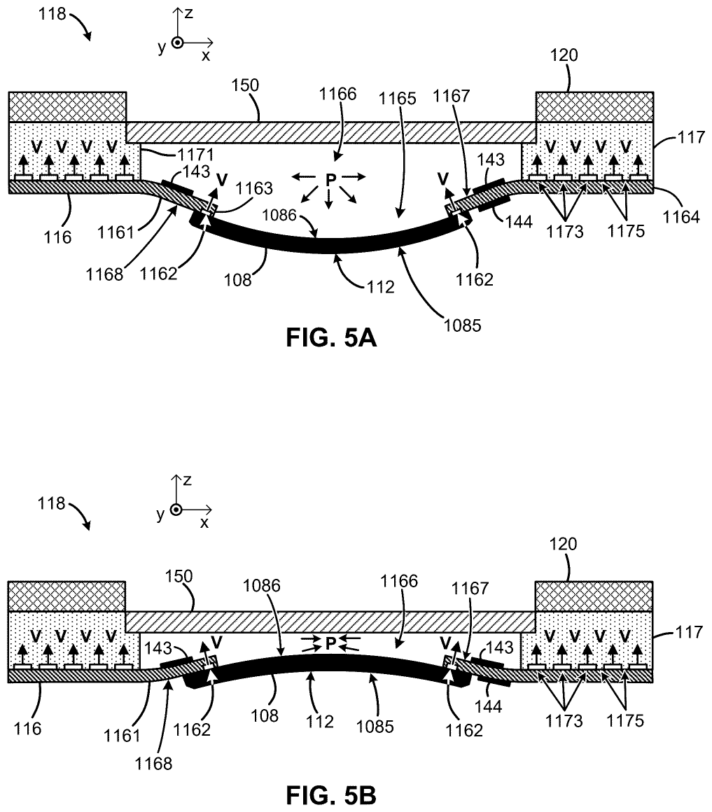

The shape of the flexible portion 1161 and the shape of the superstrate 108 may be changed by pressurizing (e.g., positively pressurizing, negatively pressurizing) the air cavity 1166. For example, FIG. 5A illustrates a cross-sectional view of an example embodiment of the superstrate-chuck assembly 118 and the superstrate 108 when the air cavity 1166 is positively pressurized with pressure P. The air cavity 1166 may be positively pressurized with pressure P prior to moving the chuck assembly 118 toward the substrate 102 or as the chuck assembly 118 moves toward the substrate 102. When pressure P is equal to the ambient pressure (not pressurized), the superstrate 108 and the flexible portion 1161 will naturally sag from the suspended weight of the superstrate 108.

The amount of pressure P may be selected such that it is sufficient to outwardly bow the superstrate 108 with a desired curvature. Consequently, the back surface 1086 of the superstrate 108 forms a concave surface as observed from the substrate chuck 104, and the front surface 1085 of the superstrate 108 forms a convex surface as observed from the light-transmitting member 150. For example, in some embodiments the pressure P is set to 0.1 to 10 kPa. At the same time, vacuums, which apply suction forces, are generated in at least some of the annular cavities 1173 and in the superstrate-holding cavity 1162. Thus, the flexible member 116 remains attached to the superstrate 108 via the superstrate-holding cavity 1162, and the flexible member 116 remains attached to the support ring 117 across the width to maintain the inflexible portion and the flexible portion 1161. Also, because of the positive pressure P, the flexible portion 1161 of the flexible member 116 bends or bows outwardly as well. The back-side strain gauges 143 and the front-side strain gauges 144 measure (detect) the strain of the flexible portion 1161 at their respective locations (the locations that correspond to the locations of the back-side strain gauges 143 and the front-side strain gauges 144) and output strain information that indicates the measured strain at their respective locations.

Also, the air cavity 1166 may be negatively pressurized with pressure P to inwardly bow the superstrate 108 with a desired curvature and to inwardly bend or bow the flexible portion 1161 of the flexible member 116. For example, FIG. 5B illustrates an example embodiment of a superstrate-chuck assembly 118 that is holding a superstrate 108 that is bowing inward (the superstrate front surface 1085 forms a concave surface). The negative pressure is applied to the back surface 1086 (including a central portion of the back surface 1086) of the superstrate 108. Also, because of the negative pressure P, the flexible portion 1161 and the superstrate-holding cavity 1162 of the flexible member 116 bends or bows inwardly as well. Consequently, the back surface 1086 of the superstrate 108 forms a convex surface, and the front surface 1085 of the superstrate 108 forms a concave surface. When the superstrate 108 is initially loaded onto the superstrate-chuck assembly 118 and held by flexible portion 1161, the superstrate 108 can sometimes also be bowing inward (the superstrate front surface 1085 forms a concave surface) even when there is no negative pressure P applied to the back surface 1086. The applicant has found that superstrate 108 can also be bowing inward after a previous separation step even when no negative pressure P is applied to the back surface 1086.

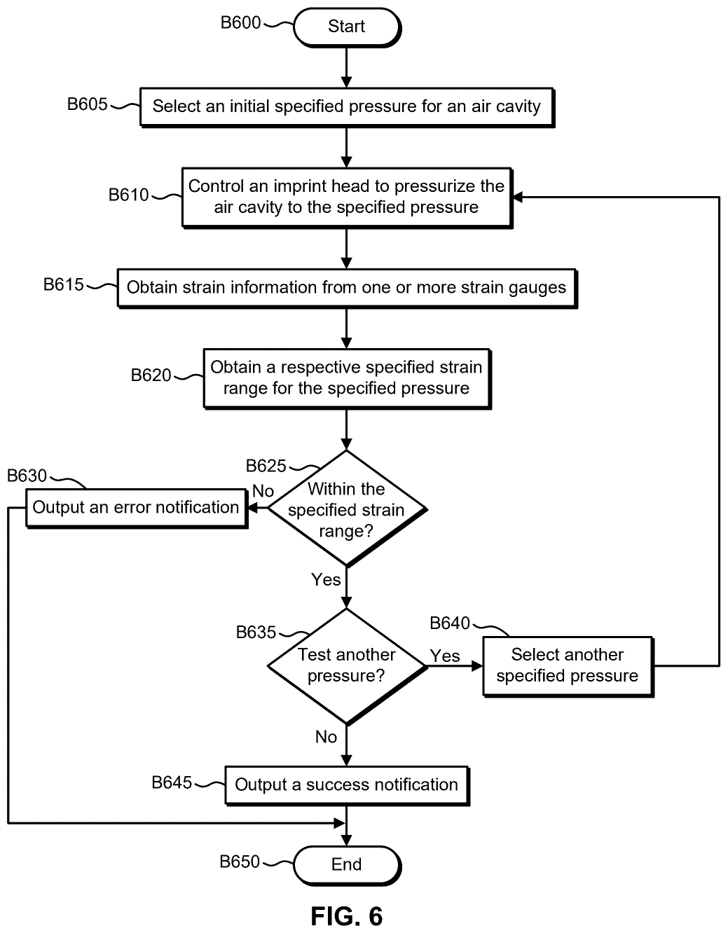

FIG. 6 illustrates an example embodiment of an operational flow for testing the condition of a flexible member. Although this operational flow and the other operational flows that are described herein are each presented in a certain respective order, some embodiments of these operational flows perform at least some of the operations in different orders than the presented orders. Examples of different orders include concurrent, parallel, overlapping, reordered, simultaneous, incremental, and interleaved orders. Also, some embodiments of these operational flows include operations (e.g., blocks) from more than one of the operational flows that are described herein. Thus, some embodiments of the operational flows may omit blocks, add blocks (e.g., include blocks from other operational flows that are described herein), change the order of the blocks, combine blocks, or divide blocks into more blocks relative to the example embodiments of the operational flows that are described herein.

Furthermore, although this operational flow and the operational flows are performed by a control device 130, some embodiments of these operational flows are performed by two or more control devices 130 or by one or more other specially-configured computing devices. Additionally, because a control device 130 may constitute a controller, some embodiments of these operational flows are performed by one or more controllers.

In FIG. 6, the flow starts in block B600 and then moves to block B605, where a control device 130 selects an initial specified pressure for an air cavity 1166 or an imprint head 119. Next, in block B610, the control device 130 controls the imprint head 119 to pressurize the air cavity 1166 to the specified pressure. For example, the control device 130 may open a vent to pressurize the air cavity 1166 to an ambient air pressure. When the air cavity 1166 is at an ambient pressure, the flexible portion 1161 and the superstrate 108 will sag so that the superstrate front surface 1085 forms a convex surface as viewed from the substrate chuck 104.

Then, in block B615, the control device 130 obtains strain information (which includes strain measurements) of the current strain of a flexible portion 1161 of a flexible member 116 from one or more strain gauges, which may include one or more back-side strain gauges 143 and may include one or more front-side strain gauges 144.

In block B620, the control device 130 obtains a respective specified strain range for the specified pressure (e.g., from storage, from another computing device, from user entry). For example, when the flexible member 116 is in good condition (e.g., operating properly), the strain measurements of the flexible portion 1161 should be the same, or approximately the same, every time the air cavity 1166 is pressurized to a particular specified pressure. The respective specified strain range for the specified pressure is the range in which the strain measurements of the flexible portion 1161 are acceptable for the specified pressure. If the strain measurements fall outside of the respective specified strain range, then the flexible portion 1161 may not be in good condition.

Next, in block B625, the control device 130 determines whether the strain measurements are within the respective specified strain range for the specified pressure. In block B625, the control device 130 may determine whether the degradation of the flexible member 116 exceeds a threshold based on the strain information. If the strain measurements are not within the respective specified strain range for the specified pressure (B625=No) (e.g., the degradation of the flexible member 116 exceeds a threshold), then the flow moves to block B630, where the control device 130 outputs an error notification, and then the flow ends in block B650. An error notification may include a message to replace the flexible member 116. If the strain measurements have a sign (positive or negative) that is opposite what is expected, the control device 130 may initiate a recovery process. The recovery process may include first ensuring that a gap between the imprint head 119 and the substrate chuck 104 is greater than a threshold so the superstrate 108 does not touch anything during the recovery process. The recovery process may further include a second step of confirming that the pressure in the air cavity 1166 is the ambient pressure or approximately the ambient pressure and holding that pressure for a first specified period (10 milliseconds-2 seconds). The recovery process may further include a third step of ramping the pressure in the air cavity 1166 to at least twice the ambient pressure or at least twice a setpoint pressure used during the shaping process and then holding that pressure for a second specified period (10 milliseconds-2 seconds). The recovery process may further include a fourth step of decreasing the pressure in the air cavity 1166 to the ambient pressure or approximately the ambient pressure in a controlled manner and then holding the ambient pressure for a third specified period (10 milliseconds-2 seconds). The recovery process may further include a fifth step of measuring a sign of the strain measurements while the pressure in the air cavity 1166 is approximately the ambient pressure.

If the strain measurements are within the respective specified strain range for the specified pressure (B625=Yes), then the flow moves to block B635.

In block B635, the control device 130 determines whether to perform blocks B610-B625 for another specified pressure. For example, the control device 130 may perform blocks B610-B625 for every specified pressure in a list (e.g., sequence) of specified pressures. If the control device 130 determines to perform blocks B610-B625 for another specified pressure, then the flow moves to block B640, where the control device 130 selects another specified pressure, and the flow then returns to block B610. If the control device 130 determines not to perform blocks B610-B625 for another specified pressure, then the flow moves to block B645, where the control device 130 outputs a success notification, and then the flow ends in block B650. In some embodiments, only ambient pressure is measured, block B635 is omitted, and the flow ends in block B650.

The control device 130 may perform the operations in FIG. 6 during a test of a flexible member 116, for example before a spread process is started or during a spread process.

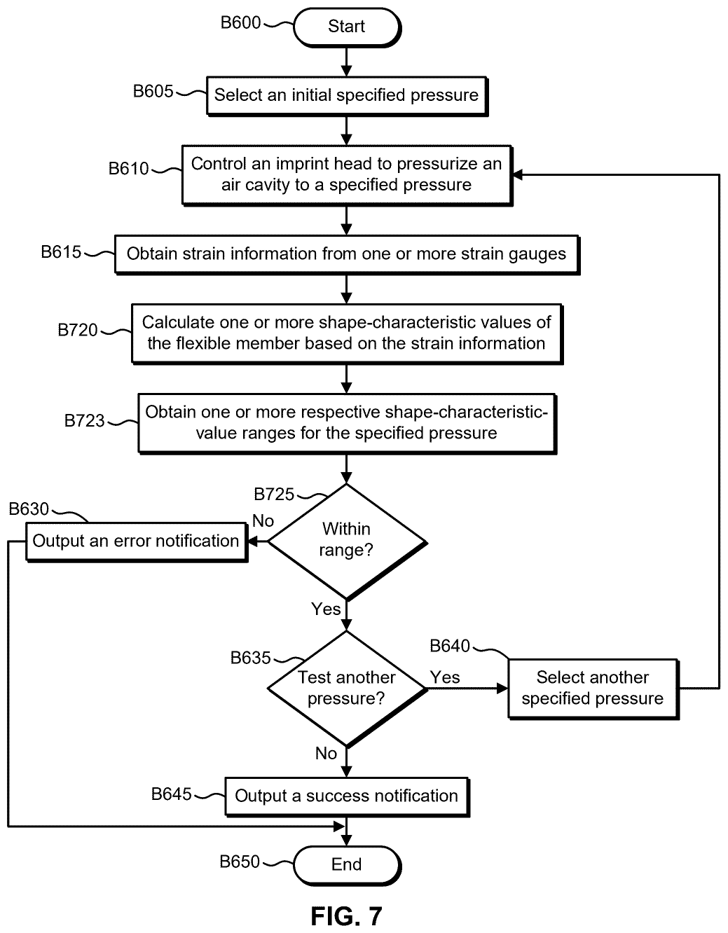

FIG. 7 illustrates an example embodiment of an operational flow for testing the condition of a flexible member. The blocks in FIG. 7 that are identical to, or substantially identical to, blocks in FIG. 6 have the same numbers as the corresponding blocks in FIG. 6, and a redundant description thereof is omitted.

In FIG. 7, from block B615, the flow moves to block B720. In block B720, the control device 130 calculates (estimates) respective values of one or more characteristics of a shape (shape-characteristic values) of the flexible member 116 at the specified pressure based on the strain information. Examples of shape characteristics include the following: a deflection amount of the flexible member 116 (e.g., a z-axis-deflection amount), an angle of the flexible member 116 (e.g., a respective tangent angle or normal angle), and a curvature of the flexible member 116.

Also, each shape-characteristic value may be defined at a respective location of the flexible member. For example, a deflection amount may be defined at a respective x-y coordinate or at a respective radial distance and azimuth (radial coordinate), an angle value may be defined at a respective x-y coordinate or at a respective radial distance and azimuth (radial coordinate), and a curvature may be defined at a respective x-y coordinate or at a respective radial distance and azimuth (radial coordinate). For example, the shape-characteristic values may include respective deflection amounts, angles, or curvatures at a plurality of locations on the flexible member 116.

Also, depending on the side of the flexible member 116 that is measured by the strain measurements, the strain measurements will be either positive or negative. In general, the strain measurements will be positive when a surface is in tension and will be negative when a surface is in compression. For example, when the flexible-member front surface 1168 is convex as illustrated in FIG. 5A, as observed from the substrate-chuck side, the back-side strain gauge 143 will supply positive strain measurements, and the front-side strain gauge 144 will supply negative strain measurements. Also, when the flexible-member front surface 1168 is concave as illustrated in FIG. 5B, as observed from the light-transmitting side 150, the back-side strain gauge 143 will supply negative strain measurements, and the front-side strain gauge 144 will supply positive strain measurements. In addition, the degree of curvature will be reflected in the magnitude of the strain measurements, depending on the radial location relative to centers of the inner or outer perimeters of the flexible portion 1161. Thus, for a particular specified pressure (for example an ambient pressure), there will be an expected magnitude and sign of the strain measurements. And shape-characteristic values of the flexible member 116 can be determined using the magnitudes and signs of the strain measurements, which can provide an estimate of the shape (and shape-characteristic values) of the flexible member 116 at the specified pressure. The applicant has found that there is a repeatable monotonic relationship between the magnitude and sign of the strain measurements and the shape-characteristic values (e.g., deflection values, angle values, and curvature values) of the shape of the flexible portion 1161.

Then, in block B723, the control device 130 obtains one or more respective ranges of the shape-characteristic values (shape-characteristic-value ranges) for the specified pressure. Block B723 may include obtaining a respective shape-characteristic-value range for each shape characteristic for which a shape-characteristic value was calculated in block B720. And the shape-characteristic-value ranges may include respective shape-characteristic-value ranges for each of a plurality of locations on the flexible member 116. For example, if two respective shape-characteristic values (for two different shape characteristics) are calculated for five locations on the flexible member 116, block B720 may include obtaining ten shape-characteristic-value ranges-one shape-characteristic-value range for each shape-characteristic value.

For example, when the flexible member 116 is in good condition (e.g., operating properly), the shape-characteristic values of the flexible portion 1161 should be the same, or approximately the same, every time the air cavity 1166 is pressurized to a particular specified pressure. The respective shape-characteristic-value range for the specified pressure is the range in which the corresponding shape of the flexible portion 1161 (as indicated by the applicable shape-characteristic values) is acceptable for the specified pressure. For example, a shape-characteristic-value range may be determined based on measurements or on beam bending theory, material properties and dimensions of the flexible portion, material properties and dimensions of the superstrate, and the air cavity pressure. If the shape-characteristic values fall outside of the respective shape-characteristic-value ranges, then the shape of the flexible portion 1161 that corresponds to the shape-characteristic values may not be acceptable and the flexible portion 1161 may not be in good condition. For example, the flexible portion 1161 may undergo slow deformation from the repeated cycling over many thousands of operations. The stress-induced deformation can cause the shape—and thus the shape-characteristic values—to be out of range for a specified pressure, which can affect the performance of the shaping system 100.

Next, in block B725, the control device 130 determines whether the shape-characteristic values are within one or more respective shape-characteristic-value ranges for the specified pressure, which indicates whether the shape of the flexible member 116 is within an acceptable range for the specified pressure. If the one or more shape-characteristic values are not within the one or more respective shape-characteristic-value ranges for the specified pressure (B725=No), then the flow moves to block B630, where the control device 130 outputs an error notification, and then the flow ends in block B650. If the one or more shape-characteristic values are within the one or more respective shape-characteristic-value ranges for the specified pressure (B725=Yes), then the flow moves to block B635.

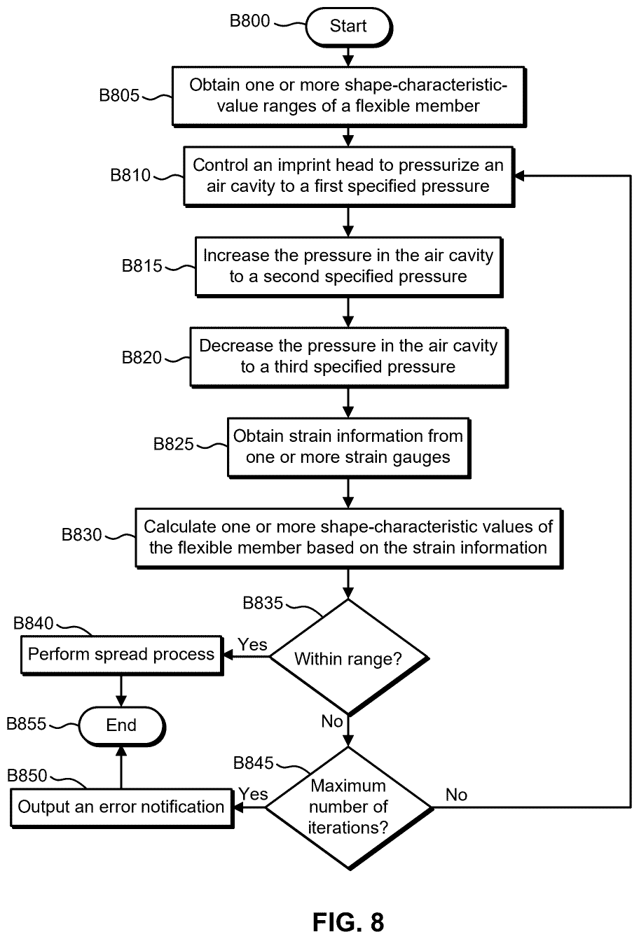

FIG. 8 illustrates an example embodiment of an operational flow for recovering the shape of a flexible member. For example, the operational flow in FIG. 8 may be performed before or after block B630 if the strain measurements are not within the respective specified range for the specified pressure (B625=No) in FIG. 6 or before or after block B630 if the one or more shape-characteristic values are not within the one or more respective shape-characteristic-value ranges for the specified pressure (B725=No) in FIG. 7.

The flow starts in block B800 and moves to block B805, where a control device 130 obtains one or more shape-characteristic-value ranges of the flexible portion 1161 of a flexible member 116. For example, the control device 130 may retrieve the one or more shape-characteristic-value ranges from storage, or the control device 130 may obtain one or more shape-characteristic-value ranges from a sensor 141 or from user entry. For example, a shape-characteristic-value range may be determined based on measurements or on beam bending theory, material properties and dimensions of the flexible portion, material properties and dimensions of the superstrate, and the air cavity pressure.

Next, in block B810, the control device 130 controls an imprint head 119 to pressurize an air cavity 1166 to a first specified pressure (or to a pressure within a first specified range of pressures). In some embodiments, the first specified air pressure is the ambient air pressure or is approximately the ambient air pressure. And the control device 130 may control the imprint head 119 to hold the first specified pressure for a first specified period.

Next, in block B815, the control device 130 controls the imprint head 119 to increase (e.g., ramp) the pressure in the air cavity 1166 to a second specified pressure (or to a pressure within a second specified range of pressures). For example, in some embodiments the second specified pressure is at least twice the ambient pressure or at least twice a setpoint pressure used during a spread process. And the control device 130 may control the imprint head 119 to hold the second specified pressure for a second specified period. The second specified pressure may be, for example, 0.7-1.3 kPa.

The flow then proceeds to block B820, where the control device 130 controls the imprint head 119 to decrease the pressure in the air cavity 1166 to a third specified pressure. The third specified pressure may be the same as the first specified pressure. Thus, in some embodiments, the third specified air pressure is the ambient air pressure or is approximately the ambient air pressure.

The flow then moves to block B825, where the control device 130 obtains strain information from one or more strain gauges (back-side strain gauges 143 or front-side strain gauges 144). Then, in block B830, the control device 130 calculates one or more shape-characteristic values of the flexible member 116 (particularly the flexible portion 1161 of the flexible member 116) based on the strain information. The applicant has found that there is a repeatable monotonic relationship between the magnitude of the strain measurements and the shape-characteristic values (e.g., deflection values, angle values, and curvature values) of the shape of the flexible portion 1161. For example, the control device 130 may calculate the respective shape-characteristic values of the curvature at different areas (e.g., different coordinates) of the flexible portion 1161.

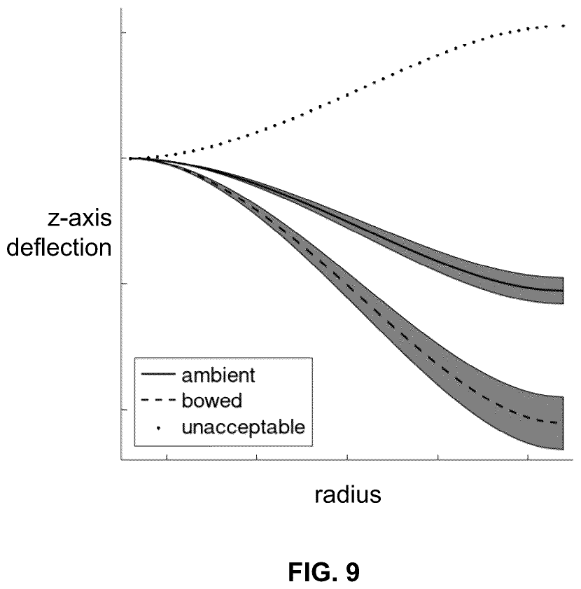

The flow then proceeds to block B835, where the control device 130 determines whether the one or more shape-characteristic values of the flexible member 116 are within respective shape-characteristic-value ranges. For example, FIG. 9 illustrates examples of the shape of the flexible portion 1161 of a flexible member 116. The right side of FIG. 9 is where the superstrate 108 is attached to the flexible member 116, and the vertical axis illustrates the deflection of the flexible member 116. FIG. 9 shows the deflection of the flexible member 116 when the flexible member 116 is in three different states. A first state (“ambient”) is when the air cavity 1166 is vented to the local atmosphere and the deflection is due solely to the weight of the superstrate 108 and the flexible portion 1161, and the contact surface 112 is in a non-contact state. A second state (“bowed”) is when the air cavity 1166 is pressurized to a specified pressure such that the superstrate 108 has the preferred bowed shaped before initial contact with the formable material 124 and the contact surface 112 is in a non-contact state. A third state (“unacceptable”) is when the air cavity 1166 is vented to the local atmosphere, the contact surface 112 is in a non-contact state, and the superstrate 108 has sprung into a metastable state such that flexible member front surface 1168 and the superstrate front surface 1085 have a concave surface. The applicant has found that this unacceptable shape sometimes happens after a separation step. For example, the flexible member 116 may be a bistable structure, and FIGS. 5A and 5B illustrate examples of two stable equilibrium states that a bistable structure may assume. The grey regions illustrate the ranges of acceptable deflection values (which are examples of shape-characteristic values) that the bowed flexible portion 1161 would have at single specified pressures.

If the control device 130 determines that the one or more shape-characteristic values of the flexible member 116 are within the respective shape-characteristic-value ranges (B835=Yes), then the flow moves to block B840, where the control device 130 controls a shaping system 100 to perform a spread process. During the spread process, the superstrate 108 is brought into contact with formable material 124 on the substrate and the formable material 124 is cured. Then the flow in FIG. 8 ends in block B855.

If the control device 130 determines that the one or more shape-characteristic values of the flexible member 116 are not within the one or more respective shape-characteristic-value ranges (B835=No), then the flow moves to block B845.

In block B845, the control device 130 determines whether a maximum number of iterations of blocks B810-B835 have been performed. If the control device 130 determines that the maximum number of iterations of blocks B810-B835 have not been performed (B845=No), then the returns to block B810.

If the control device 130 determines that the maximum number of iterations of blocks B810-B835 have been performed (B845=Yes), then the flow moves to block B850. In block B850, the control device 130 outputs an error notification, and then the flow ends in block B855. The error notification may include one or more of the following: updating a database, sending information to one or more operators or devices, and opening a dialog box in a user interface.

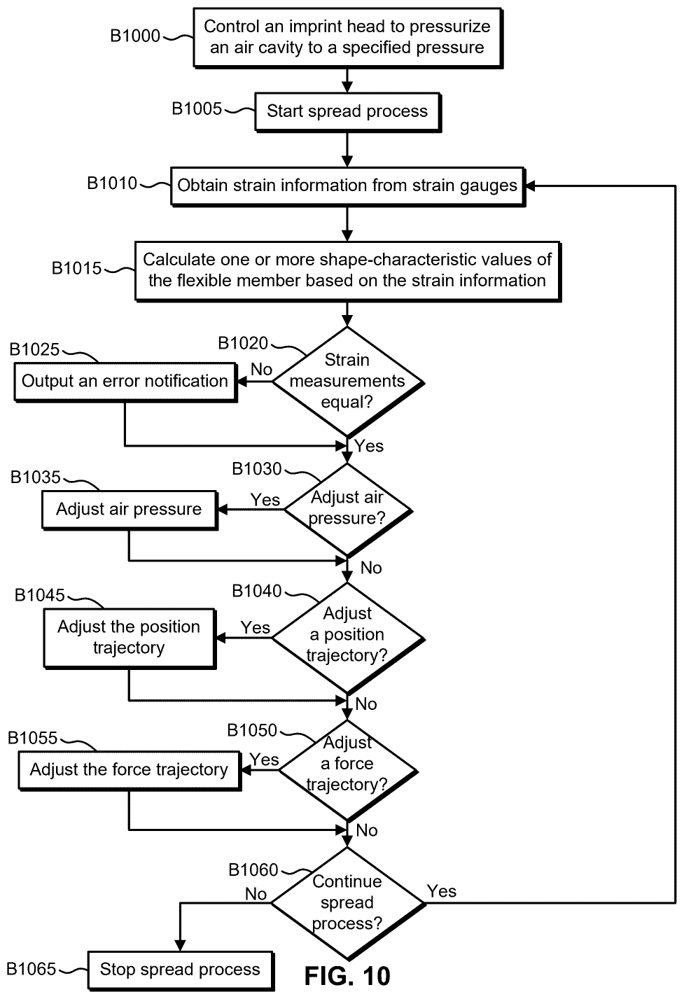

FIG. 10 illustrates an example embodiment of an operational flow for performing a spread process.

In block B1000, a control device 130, which controls a shaping system 100, controls an imprint head 119 to pressurize an air cavity 1166 to a specified pressure. Next, in block B1005, the control device 130 controls the shaping system 100 to start a spread process, which includes bringing a superstrate 108 into contact with formable material 124 that has been deposited on a substrate 102.

Then, in block B1010, the control device 130 obtains strain information (which includes strain measurements) indicating the current strain of a flexible portion 1161 of a flexible member 116 from strain gauges (back-side strain gauges 143 or front-side strain gauges 144) (e.g., as described in block B615 in FIG. 6).

The flow then moves to block B1015, where the control device 130 calculates one or more shape-characteristic values of the flexible member 116 based on the strain information (e.g., as described in block B720 in FIG. 7). Also, in some embodiments, the control device 130 calculates one or more shape-characteristic values of the superstrate 108 based on the strain information in addition to, or in alternative to, the shape-characteristic values of the flexible member 116. Thus, some embodiments use both the shape-characteristic values of the superstrate 108 and the shape-characteristic values of the flexible member 116 in blocks B1030, B1040, and B1050, and some embodiments substitute the shape-characteristic values of the superstrate 108 for the shape-characteristic values of the flexible member 116 in blocks B1030, B1040, and B1050.

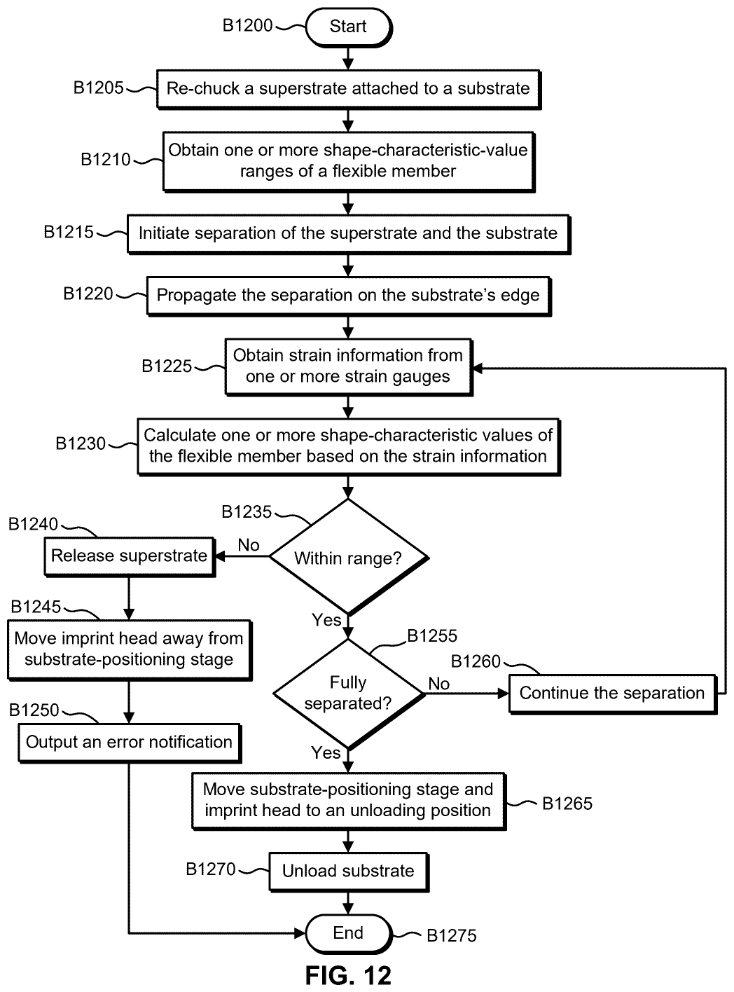

In blocks B1010-B1020 (as well as in blocks B615-B620 in FIG. 6, blocks B615-B720 in FIG. 7, blocks B825-B830 in FIG. 8, and blocks B1225-B1230 in FIG. 12), the strain measurements from each of the plurality of strain gauges may be transformed into position-independent strain measurements that remove the affect of the radial measured location and the affect of the side of the flexible member to which the strain gauge is attached. Next, in block B1020, the control device 130 determines whether the respective strain measurements (e.g., position-independent strain measurements) that were measured by a strain gauge are within a range of or equal to the respective strain measurements (e.g., position-independent strain measurements) that were measured by the other strain gauges. If the strain measurements are not equal or are outside the range (e.g., the difference between the strain measurements of any two of the strain gauges is greater than the range) (B1020=No), which indicates that at least one strain gauge detected a strain measurement that was different from the strain measurements that were detected by the other strain gauges, then the flow moves to block B1025, where the control device 130 outputs an error notification, and then the flow moves to block B1030. If the strain measurements are equal (e.g., the maximum of the pairwise differences between the strain measurements of the strain gauges is within the range) (B1020=Yes), then the flow proceeds to block B1030.

In block B1030, the control device 130 determines whether to adjust the air pressure in the air cavity 1166 based on the one or more shape-characteristic values of the flexible member 116. If the control device 130 determines to adjust the air pressure in the air cavity 1166 (B1030=Yes), then the flow advances to block B1035, where the control device 130 controls the imprint head 119 to adjust the air pressure in the air cavity 1166. For example, if a shape-characteristic value is below a respective shape-characteristic-value range for a particular time during the spread process, then the pressure in the air cavity 1166 can be increased; likewise when the shape-characteristic value is above the respective shape-characteristic-value range, then the pressure in the air cavity 1166 can be decreased. The flow then moves to block B1040. If the control device 130 determines not to adjust the air pressure in the air cavity 1166 (B1030=No), then the flow moves to block B1040.

In block B1040, the control device 130 determines whether to adjust the position trajectory of the superstrate 108 based on the one or more shape-characteristic values of the flexible member 116. If the control device 130 determines to adjust the position trajectory of the superstrate 108 (B1040=Yes), then the flow advances to block B1045. In block B1045, the control device 130 controls the imprint head 119 to adjust the position trajectory of the superstrate 108. For example, if a shape-characteristic value is below a respective shape-characteristic-value range for a particular time during the spread process, then the speed at which the imprint head 119 moves toward the substrate chuck 104 can be decreased; likewise when the shape-characteristic value is above a respective shape-characteristic-value range, then the speed at which the imprint head 119 moves toward the substrate chuck 104 can be increased. Also for example, if a shape-characteristic value is above a respective shape-characteristic-value range for a particular time during the spread process, then a relative tilt of the imprint head 119 to the substrate chuck 104 can be adjusted. The flow then advances to block B1050. If the control device 130 determines not to adjust the position trajectory of the superstrate 108 (B1040=No), then the flow moves to block B1050.

In block B1050, the control device 130 determines whether to adjust the force trajectory of the superstrate 108 based on the one or more shape-characteristic values of the flexible member 116. If the control device 130 determines to adjust the force trajectory of the superstrate 108 (B1050=Yes), then the flow advances to block B1055. In block B1055, the control device 130 controls the imprint head 119 to adjust the force trajectory of the superstrate 108, which may include an adjustment of only the force. For example, in some embodiments, if a shape-characteristic value is below a shape-characteristic-value range for a particular time during the spread process, then the force that the imprint head 119 applies is either reduced, kept the same, or the rate of increase is reduced. In the case when the shape-characteristic value is above the shape-characteristic-value range, then either the force that the imprint head 119 applies is increased or the rate of increase of the force that the imprint head 119 applies is increased. The flow then advances to block B1060. If the control device 130 determines not to adjust the force trajectory of the superstrate 108 (B1050=No), then the flow moves to block B1060.

In block B1060, the control device 130 determines whether to continue the spread process. For example, the control device 130 may determine not to continue the spread process if the strain measurements are not equal or are outside a range in block B1020 or if the spread process is finished. If the control device 130 determines to continue the spread process (B1060=Yes), then the flow returns to block B1010. If the control device 130 determines not to continue the spread process (B1060=No), then the flow ends in block B1065.

Some embodiments of the control device 130 perform the operations in FIG. 10 to control the curvature of the superstrate 108 just in front of the spread front (the superstrate-to-substrate-contact front). During the advance of the spread front, the curvature decreases for a set pressure. Such embodiments of the control device 130 use the strain measurements to detect the superstrate curvature, as indicated by the one or more shape-characteristic values, during the spread process. If, for example, the strain measurements indicate a curvature that is too small (which may trap air bubbles), then the pressure in the air cavity 1166 can be increased to increase the superstrate curvature. The force trajectory, the position trajectory, or both are used to advance the spread front to complete the spreading process. Additionally, such embodiments of the control device 130 may control the air pressure, the position trajectory, and the force trajectory to make the spread front radially uniform (a lack of radial uniformity may indicate a tilt error and can lead to filling issues).

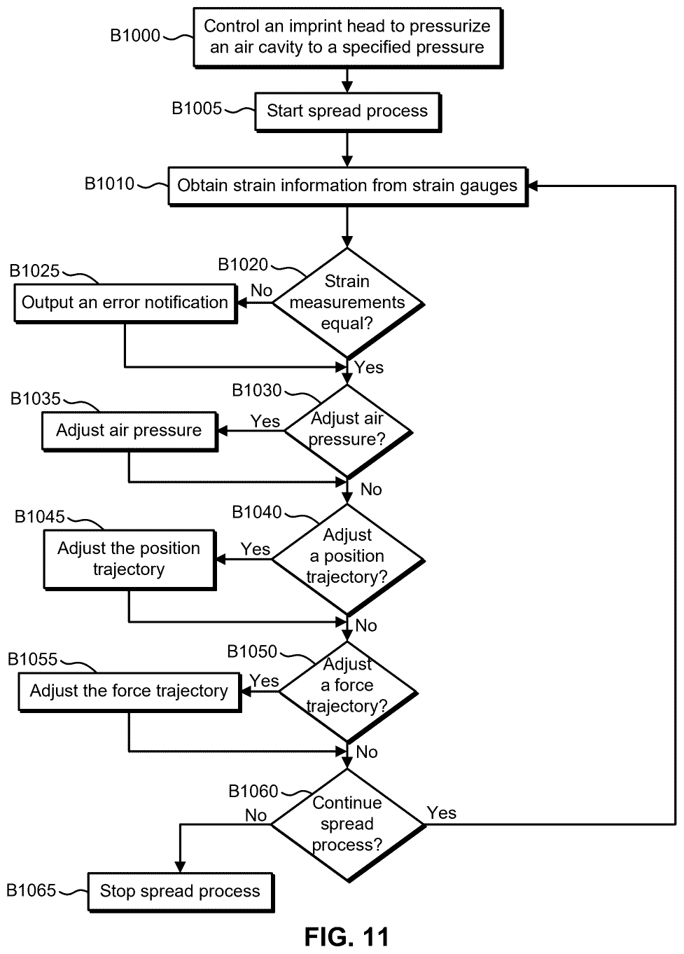

FIG. 11 illustrates an example embodiment of an operational flow for performing a spread process. The flow in FIG. 11 is similar to the flow in FIG. 10. However, FIG. 11 omits block B1015. Thus, the operations in blocks B1030, B1040, B1050, and B1060 are based on the strain information but are not based on either the shape-characteristic values of the flexible member 116 or the shape-characteristic values of the superstrate 108.

FIG. 12 illustrates an example embodiment of an operational flow for separating a superstrate from a substrate. The flow starts in block B1200, and when the flow starts, a superstrate 108 is in contact with cured formable material 124 on a substrate 102. Curing the formable material 124 on the substrate 102 while the formable material 124 is in contact with the superstrate 108 forms a cured planarized layer 1027 on which the superstrate 108 is resting. The superstrate 108 is adhered to the cured planarized layer 1027 with a specific controlled adhesion force. Separating the superstrate 108 from the cured planarized layer 1027 in a controlled manner is necessary for preserving nanometric planarization of the cured planarized layer 1027.

Next, in block B1205, the control device 130 controls an imprint head 119 to re-chuck the superstrate 108 that is attached to the substrate 102. Prior to the curing of the formable material 124, the superstrate 108 is released from the flexible member 116. The re-chucking includes causing the flexible member 116 to grip the superstrate 108 in some manner (vacuum force, electrostatic force, etc.).

In block B1210, the control device 130 obtains one or more shape-characteristic-value ranges of a flexible member 116 (e.g., as described in block B805 in FIG. 8). The one or more shape-characteristic-value ranges may include a series of shape-characteristic-value ranges that correspond to different times during a separation process. For example, the one or more shape-characteristic-value ranges may include a set of shape-characteristic-value ranges for time t, a set of shape-characteristic-value ranges for time 2t, a set of shape-characteristic-value ranges for time 3t, etc.

Then, in block B1215, the control device 130 controls the shaping system 100 to initiate separation of the superstrate 108 and the substrate 102. For example, the control device 130 may control a pushpin in the substrate chuck 104 or in the substrate-positioning stage 107 to move in the direction of the superstrate 108 and start pushing the superstrate 108 away from the substrate 102, and/or the control device 130 can control one or both of the imprint head 119 and the substrate-positioning stage 107 to move away from the other.

The flow continues to block B1220, where the control device 130 controls the shaping system 100 to propagate the separation on the substrate's edges, for example by controlling one or both of the imprint head 119 and the substrate-positioning stage 107 to move away, or continue moving away, from the other.

In block B1225 (which may be performed concurrently with any of blocks B1215-B1220 and B1230-B1270), the control device 130 obtains strain information (which includes strain measurements) from one or more strain gauges (back-side strain gauges 143 or front-side strain gauges 144).

Then, in block B1230, the control device 130 calculates one or more shape-characteristic values (e.g., a curvature value, a deformation value, a slope value) of the flexible member 116 (including the flexible portion 1161 of the flexible member 116) based on the strain information. For example, the control device 130 may calculate the respective curvature value of different areas of the flexible portion 1161. Also, in some embodiments, the control device 130 calculates one or more shape-characteristic values of the superstrate 108 based on the strain information in addition to, or in alternative to, the one or more shape-characteristic values of the flexible member 116. Thus, some embodiments use both the shape-characteristic values of the superstrate 108 and the shape-characteristic values of the flexible member 116 in block B1235, and some embodiments substitute the shape-characteristic values of the superstrate 108 for the shape-characteristic values of the flexible member 116 in block B1235. And embodiments that use the shape-characteristic values of the superstrate 108 obtain one or more shape-characteristic-value ranges of the superstrate 108 in block B1210.

The flow then proceeds to block B1235, where the control device 130 determines whether the one or more shape-characteristic values of the flexible member 116 (or, in some embodiments, the shape-characteristic values of the superstrate 108) are within the one or more respective shape-characteristic-value ranges. The shape-characteristic-value ranges in block B1235 may be different from the shape-characteristic-value ranges in block B825. For example, the shape-characteristic-value ranges in block B825 may correspond to a shape (including a curvature) or a shape range (e.g., a range of curvatures) that is acceptable for a spread process, and the shape-characteristic-value ranges in block B1235 may correspond to a shape (including a curvature) or a shape range (e.g., a range of curvatures) that is acceptable for a separation process. For example, a shape-characteristic value (e.g., curvature value) that is not within a respective shape-characteristic-value range in block B1235 may correspond to shapes that would cause damage to the flexible member 116 if the flexible member 116 assumed such shapes. The flexible portion 1161 can also take on shapes in which the superstrate 108 starts to be released from the flexible portion 1161 in an uncontrolled manner, which can damage one or more of the following: the cured planarized layer 1027, the flexible portion 1161, and the superstrate 108.

If the control device 130 determines that the one or more shape-characteristic values of the flexible member 116 are not within the one or more shape-characteristic-value ranges (B1235=No) (for example, the one or more shape-characteristic-value ranges that correspond to the current time in the separation process), then the flow moves to block B1240, where the control device 130 controls the flexible member 116 to release the superstrate 108 in a controlled manner. Then, in block B1245, the control device 130 controls the shaping system 100 to move the imprint head 119 away from the substrate-positioning stage 107. In block B1250, the control device 130 outputs an error notification (which, as noted above, may include a message to replace the flexible member 116), and then the flow ends in block B1275.

If the control device 130 determines that the one or more shape-characteristic values of the flexible member 116 are within the one or more shape-characteristic-value ranges (B1235=Yes), then the flow moves to block B1255.

In block B1255, the control device 130 determines whether the superstrate 108 and the substrate 102 are fully separated. For example, the control device 130 may determine whether the superstrate 108 and the substrate 102 are fully separated based on signals from at least one sensor 141, from sensors that record the current positions of the imprint head 119 or the substrate-positioning stage 107, or from the current positions of one or more step motors that move the imprint head 119 or the substrate-positioning stage 107.

If the control device 130 determines that the superstrate 108 and the substrate 102 are not fully separated (B1255=No), then the flow proceeds to block B1260. In block B1260, the control device 130 controls the shaping system 100 to continue the separation of the imprint head 119 from the substrate-positioning stage 107. The flow then returns to block B1225. If the control device 130 determines that the superstrate 108 and the substrate 102 are fully separated (B1255=Yes), then the flow proceeds to block B1265.

In block B1265, the control device 130 controls the shaping system 100 to move the imprint head 119 and the substrate-positioning stage 107 to an unloading position. In block B1270, the control device 130 controls the shaping system 100 to unload the substrate 102, for example by controlling the substrate chuck 104 to release the substrate 102, by controlling lift pins to raise the substrate 102, and by controlling a transfer robot to remove the substrate 102 from the substrate chuck 104.

Finally, the flow ends in block B1275.

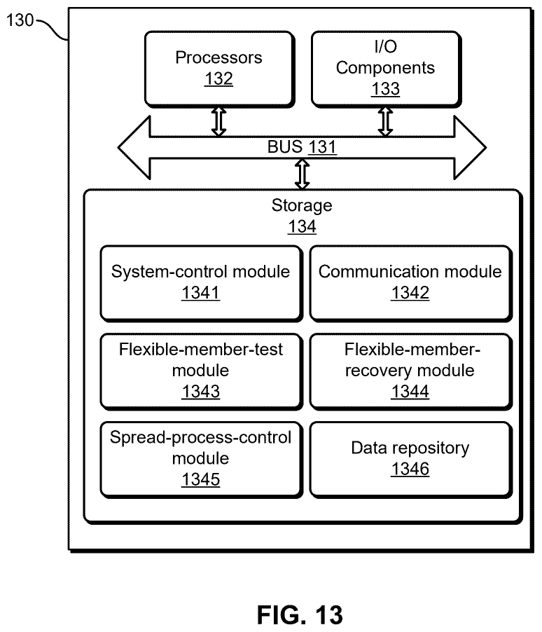

FIG. 13 is a schematic illustration of an example embodiment of a control device 130. The control device 130 includes one or more processors 132, one or more computer-readable storage media 134, one or more I/O components 133, and a bus 131.

The one or more processors 132 are or include one or more central processing units (CPUs), such as microprocessors (e.g., a single core microprocessor, a multi-core microprocessor); one or more graphics processing units (GPUs); one or more application-specific integrated circuits (ASICs); one or more field-programmable-gate arrays (FPGAs); one or more digital signal processors (DSPs); or other electronic circuitry (e.g., other integrated circuits). Furthermore, a processor 132 may be a purpose-built controller or may be a general-purpose controller. The one or more processors 132 may include a plurality of processors that include processors that are both (i) included in the control device 130 and (ii) in communication with the shaping system 100 but not included in the control device 130. And the one or more processors 132 are an example of a processing unit.

The one or more processors 132 may operate based on computer-readable instructions (e.g., in one or more programs) stored on one or more computer-readable storage media 134. As used herein, a computer-readable storage medium 134 is a computer-readable medium that includes an article of manufacture, for example a magnetic disk (e.g., a floppy disk, a hard disk), an optical disc (e.g., a CD, a DVD, a Blu-ray), a magneto-optical disk, magnetic tape, and semiconductor memory (e.g., a non-volatile memory card, flash memory, a solid-state drive, SRAM, DRAM, EPROM, EEPROM). And examples of the one or more computer-readable storage media 134 include networked-attached storage (NAS) devices, intranet-connected storage devices, and internet-connected storage devices. The one or more computer-readable storage media 134, which may include both ROM and RAM, can store computer-readable data or computer-executable instructions. Furthermore, in embodiments where the one or more computer-readable storage media 134 include RAM, the one or more processors 132 can use the RAM as a work area. Additionally, when the control device 130 or the one or more processors 132 are described as obtaining information or data, recording information or data, generating information or data, storing information or data, operating on information or data, processing information or data, etc., the information or data are stored in the one or more computer-readable storage media 134. Also, the one or more computer-readable storage media 134 are an example of a storage unit. And the computer-readable storage media 134 may be distributed among multiple processors 132.

The control device 130 also includes I/O components 133. The I/O components 133 include physical interfaces and communication components (e.g., a GPU, a network-interface controller) that enable communication (wired or wireless) with other members of a shaping system 100 (e.g., a substrate chuck 104, a substrate-positioning stage 107, an imprint head 119, a sensor 141, a fluid dispenser 122, an energy source 126, an imaging device 156, a substrate-heating subsystem 166, back-side strain gauges 143, front-side strain gauges 144, motors or actuators 1091, a vacuum source 165), with other computing devices (e.g., a networked computer), and with input or output devices, which may include a display device, a network device, a keyboard, a mouse, a printing device, a light pen, an optical-storage device, a scanner, a microphone, a drive, a joystick, and a control pad.

Also, the hardware components of the control device 130 communicate via one or more buses 131 or other electrical connections. Examples of buses 131 include a universal serial bus (USB), an IEEE 1394 bus, a PCI bus, an Accelerated Graphics Port (AGP) bus, a Serial AT Attachment (SATA) bus, and a Small Computer System Interface (SCSI) bus.

The control device 130 additionally includes a system-control module 1341, a communication module 1342, a flexible-member test module 1343, a flexible-member recovery module 1344, and a spread-process control module 1345. As used herein, a module includes logic, computer-readable data, or computer-executable instructions. In the embodiment shown in FIG. 13, the modules are implemented in software (e.g., Assembly, C, C++, C#, Java, JavaScript, BASIC, Perl, Visual Basic, Python, PHP). However, in some embodiments, the modules are implemented in hardware (e.g., customized circuitry) or, alternatively, a combination of software and hardware. When the modules are implemented, at least in part, in software, then the software can be stored in the one or more computer-readable storage media 134. Also, in some embodiments, the control device 130 includes additional or fewer modules, the modules are combined into fewer modules, or the modules are divided into more modules. And each of these modules may use (e.g., call) other modules. Also, the control device 130 includes a data repository 1346, which stores information, such as control information, specified pressures (e.g., lists of specified pressures), pressure ranges, strain ranges, shape-characteristic-value ranges, shape-characteristic values, test-pressure plans (e.g., sequences of test pressures), strain information, and a maximum number of iterations.

The system-control module 1341 includes instructions that cause and enable the applicable components (e.g., the one or more processors 132, the storage 134, the I/O components 133) of the control device 130 to communicate with and to control the other members of a shaping system 100. For example, some embodiments of the system-control module 1341 include instructions that cause the applicable components of the control device 130 to control the applicable components of a shaping system 100 to perform at least some of the operations that are described in blocks B610 and B615 in FIGS. 6 and 7; in blocks B810, B815, B830, and B840 in FIG. 8; in blocks B1000, B1005, B1010, B1035, B1045, B1055, and B1065 in FIGS. 10 and 11; and in blocks B1205, B1215, B1220, B1225, B1240, B1245, B1260, B1265, and B1270 in FIG. 12. The applicable components of the control device 130 operating according to the system-control module 1341 realize an example of a system-control unit.

The communication module 1342 includes instructions that cause the applicable components (e.g., the one or more processors 132, the storage 134, the I/O components 133) of the control device 130 to communicate with one or more other computing devices. And the applicable components operating according to the communication module 1342 realize an example of a communication unit.

The flexible-member-test module 1343 includes instructions that cause the applicable components (e.g., the one or more processors 132, the storage 134, the I/O components 133) of the control device 130 to control a shaping system 100 to test the condition of a flexible member 116. For example, some embodiments of the flexible-member-test module 1343 include instructions that cause the applicable components of the control device 130 to control the applicable components of a shaping system 100 to perform at least some of the operations that are described in FIG. 6 and FIG. 7. The flexible-member-test module 1343 may call the system-control module 1341. And the applicable components of the control device 130 operating according to the flexible-member-test module 1343 realize an example of a flexible-member-test unit.

The flexible-member-recovery module 1344 includes instructions that cause the applicable components (e.g., the one or more processors 132, the storage 134, the I/O components 133) of the control device 130 to perform a process to recover the shape of a flexible member 116. For example, some embodiments of the flexible-member-recovery module 1344 include instructions that cause the applicable components of the control device 130 to control the applicable components of a shaping system 100 to perform at least some of the operations that are described in FIG. 8. The flexible-member-recovery module 1344 may call the system-control module 1341. And the applicable components of the control device 130 operating according to the flexible-member-recovery module 1344 realize an example of a flexible-member-recovery unit.

The spread-process-control module 1345 includes instructions that cause the applicable components (e.g., the one or more processors 132, the storage 134, the I/O components 133) of the control device 130 to control a shaping system 100 to perform a spread process. For example, some embodiments of the spread-process-control module 1345 include instructions that cause the applicable components of the control device 130 to control the applicable components of a shaping system 100 to perform at least some of the operations that are described in FIG. 11 and FIG. 12. The spread-process-control module 1345 may call the system-control module 1341. And the applicable components of the control device 130 operating according to the spread-process-control module 1345 realize an example of a spread-process-control unit.

At least some of the above-described devices, systems, and methods can be implemented, at least in part, by providing one or more computer-readable media that contain computer-executable instructions for realizing the above-described operations to one or more computing devices that are configured to read and execute the computer-executable instructions. The systems or devices perform the operations of the above-described embodiments when executing the computer-executable instructions. Also, an operating system on the one or more systems or devices may implement at least some of the operations of the above-described embodiments.

Furthermore, some embodiments use one or more functional units to implement the above-described devices, systems, and methods. The functional units may be implemented in only hardware (e.g., customized circuitry) or in a combination of software and hardware (e.g., a microprocessor that executes software).

In the description, specific details are set forth in order to provide a thorough understanding of the embodiments disclosed. However, well-known methods, procedures, components and circuits may not have been described in detail in order to avoid unnecessarily lengthening the present disclosure.

Also, if a member (e.g., element, part, component) is referred herein as being “on,” “against,” “connected to,” or “coupled to” another member, then the member can be directly on, against, connected or coupled to the other member, but intervening members may also be present between the member and the other member. In contrast, if a member is referred to as being “directly on,” “directly against,” “directly connected to,” or “directly coupled to” another member, then there are no intervening members present between the member and the other member.

Furthermore, the terms “comprising,” “having,” “includes,” “including,” and “containing” are to be construed as open-ended terms unless otherwise noted. Accordingly, these terms, when used in the present specification, specify the presence of described features, integers, steps, operations, elements, materials, or members, but do not preclude the presence or addition of one or more other features, integers, steps, operations, elements, materials, or members that are not explicitly described.

1. A shaping system comprising:
an annular flexible chuck for holding a superstrate;
an air cavity enclosed in part by a flexible portion of the annular flexible chuck;
a pressure controller for applying air pressure to the air cavity, while the annular flexible chuck holds the superstrate, causing the flexible portion and the superstrate to bow;
strain gauges positioned on the flexible portion of the annular flexible chuck; and
a controller configured to estimate a curvature of the annular flexible chuck based on strain information received from the strain gauges and adjust the shaping system based on the curvature.

2. The shaping system of claim 1, wherein adjusting includes one or more of:
sending a notification about replacing the annular flexible chuck;
adjusting the air pressure in the air cavity;
adjusting a position trajectory applied to the annular flexible chuck; and
adjusting a force trajectory applied to the annular flexible chuck.

3. The shaping system of claim 1, wherein the controller is configured to:
start separation of the superstrate from cured formable material on a substrate;
estimate the curvature during the separation based on the strain information received from the strain gauges; and
control the separation based on the curvature.

4. The shaping system of claim 1, wherein the controller is configured to:
send instructions to the pressure controller to apply a first pressure to the air cavity;
estimate the curvature prior to the superstrate contacting formable material on a substrate;
send instructions to reduce the air pressure in the cavity and reapply the air pressure, based on the curvature; and
send instructions to move the annular flexible chuck towards a substrate chuck based on the curvature.

5. The shaping system of claim 1, wherein the controller is further configured to:
estimate a curvature of the superstrate based on the curvature of the annular flexible chuck.

6. The shaping system of claim 1, wherein the controller is further configured to:
detect whether the curvature of the annular flexible chuck is a first shape; and
in response to detecting that the curvature of the annular flexible chuck is a first shape, stopping a movement of the annular flexible chuck.

7. The shaping system of claim 1, wherein the controller is further configured to:
detect whether the curvature of the annular flexible chuck is a first shape; and
in response to detecting that the curvature of the annular flexible chuck is a first shape,
(i) send instructions to the pressure controller to increase the air pressure in the air cavity, then reduce the air pressure in the air cavity, and then repressurize the air cavity,
(ii) estimate a new curvature of the annular flexible chuck based on strain information received from the strain gauges after the reduction of the air pressure in the air cavity, and
(iii) detect whether the new curvature of the annular flexible chuck is the first shape.

8. The shaping system of claim 7, wherein the controller is further configured to repeat (i), (ii), and (iii) until the new curvature of the annular flexible chuck has a second shape different from the first shape.

9. The shaping system of claim 1, wherein the strain gauges are located inside the air cavity.

10. A method comprising:
applying air pressure to an air cavity enclosed in part by a flexible portion of an annular flexible chuck and a superstrate of a shaping system, wherein the annular flexible chuck holds the superstrate, and wherein applying the air pressure to the air cavity causes the flexible portion and the superstrate to bow;
obtaining strain information about the flexible portion of the annular flexible chuck;
and
adjusting the shaping system based on the strain information.

11. The method of claim 10, wherein adjusting the shaping system based on the strain information includes one or more of:
sending a notification about replacing the annular flexible chuck;
adjusting the air pressure in the air cavity;
adjusting a position trajectory applied to the annular flexible chuck; and
adjusting a force trajectory applied to the annular flexible chuck.

12. The method of claim 10, further comprising:
starting separation of the superstrate from cured formable material on a substrate;
estimating a curvature of the annular flexible chuck during the separation based on the strain information; and
controlling the separation based on the curvature.

13. The method of claim 10, further comprising:
applying a first pressure to the air cavity;
estimating, based on the strain information, a curvature of the annular flexible chuck prior to the superstrate contacting formable material on a substrate;
reducing the air pressure in the cavity and reapplying the air pressure, based on the curvature; and
moving the annular flexible chuck towards a substrate chuck based on the curvature.

14. The method of claim 10, further comprising:
detecting that degradation of the annular flexible chuck exceeds a threshold based on the strain information.

15. The method of claim 10, further comprising:
detecting, based on the strain information, whether a curvature of the annular flexible chuck is a first shape; and
in response to detecting that the curvature of the annular flexible chuck is a first shape, stopping a movement of the annular flexible chuck.

16. The method of claim 10, further comprising:
detecting, based on the strain information, whether a curvature of the annular flexible chuck is a first shape; and
in response to detecting that the curvature of the annular flexible chuck is a first shape,
(i) increasing the air pressure in the air cavity, then reducing the air pressure in the air cavity, and then repressurizing the air cavity,
(ii) estimating a new curvature of the annular flexible chuck based on strain information received after the reduction of the air pressure in the air cavity, and
(iii) detecting whether the new curvature of the annular flexible chuck is the first shape.

17. The method of claim 16, further comprising:
repeating (i), (ii), and (iii) until the new curvature of the annular flexible chuck has a second shape different from the first shape.

18. The method of claim 16, further comprising:
bringing the superstrate into contact with formable material on a substrate;
separating the superstrate from the formable material on the substrate; and
processing the formable material and the substrate to manufacture a plurality of articles.

19. A shaping system comprising:
an annular flexible chuck adapted to hold a superstrate;
a pressure controller adapted to increase or decrease an air pressure in an air cavity enclosed in part by a flexible portion of the annular flexible chuck, wherein increasing or decreasing the air pressure while the annular flexible chuck holds the superstrate causes the flexible portion and the superstrate to bow;
strain gauges that are configured to measure strain at different locations on the flexible portion of the annular flexible chuck and to generate strain measurements that indicate the measured strain; and
a controller configured to estimate one or more shape-characteristic values of the annular flexible chuck based on the strain measurements received from the strain gauges and adjust the shaping system based on the one or more shape-characteristic values.

20. The shaping system of claim 19, wherein adjusting the shaping system includes one or more of:
sending a notification about replacing the annular flexible chuck;
adjusting the air pressure in the air cavity;
adjusting a position trajectory applied to the annular flexible chuck; and
adjusting a force trajectory applied to the annular flexible chuck.
